(19) United States
(12) Patent Application Publication
(10) Pub. No.: US 2026/0129821 A1
(43) Pub. Date: May 7, 2026

(54) SEMICONDUCTOR DEVICES AND METHODS OF FORMING THE SAME

(71) Applicant: Taiwan Semiconductor Manufacturing Company, Ltd., Hsin-Chu (TW)

(72) Inventors: Jui-Lin Chen, Hsinchu (TW); Yung-Ting Chang, New Taipei City (TW); Yu-Bey Wu, Hsinchu City (TW)

(21) Appl. No.: 18/934,613

(22) Filed: Nov. 1, 2024

(51) Int. Cl. H10B 10/00

(52) U.S. Cl. CPC H10B 10/125

(57) ABSTRACT

Semiconductor devices and methods are provided. An exemplary method includes receiving a transistor comprising a gate structure over a channel region, first and second source/drain features coupled to the channel region, and a dielectric structure over the first and the second source/drain features; forming a first trench extending through the dielectric structure to expose the first source/drain feature and a second trench extending through the dielectric structure to expose the second source/drain feature; forming a mask layer covering the first trench, wherein an opening of the mask layer exposes a portion of the second trench; after the forming of the mask layer, performing an ion implantation process to form a doped region in the second source/drain feature; and after the performing of the ion implantation process, forming a first source/drain contact in the first trench and a second source/drain contact in the second trench.

### BACKGROUND

In deep sub-micron integrated circuit technology, an embedded static random access memory (SRAM) device has become a popular storage unit of high speed communication, image processing and system-on-chip (SOC) products. The amount of embedded SRAM in microprocessors and SOCs increases to meet the performance requirement in each new technology generation. Performances of transistors in an SRAM cell may affect a minimum operating voltage (Vmin) of the SRAM cell. This may lead to sub-par SRAM performance or even device failures. Therefore, although existing memory devices have been generally adequate for their intended purposes, they have not been entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a diagrammatic plan view of an IC chip, in portion or entirety, according to various aspects of the present disclosure.

FIG. 1B is a diagrammatic plan view of an array of memory cells, such as static random-access memory (SRAM) cells, in portion or entirety, according to various aspects of the present disclosure.

FIG. 2 is a circuit diagram of a memory cell, such as an SRAM cell, that can be implemented in the IC chip of FIG. 1, according to various aspects of the present disclosure.

FIG. 3 illustrates a fragmentary layout of a memory device including the SRAM cell, according to various aspects of the present disclosure.

FIG. 4 illustrates a flow chart of a method for forming a memory device including the SRAM cell, according to one or more aspects of the present disclosure.

FIGS. 5, 6, 11, 12, 13 illustrate fragmentary top views of the memory device during various fabrication stages in the method of FIG. 4, according to one or more aspects of the present disclosure.

FIGS. 6A, 7A, 8A, 9A, 10A, 11A, 12A, 13A, 14A, 15A, 17, 18 illustrate fragmentary cross-sectional views of the memory device taken along line A-A shown in FIG. 3 or line A′-A′ shown in FIG. 6 during various fabrication stages in the method of FIG. 4, according to one or more aspects of the present disclosure.

FIGS. 6B, 7B, 8B, 9B, 10B, 11B, 12B, 13B, 14B, 15B illustrate fragmentary layouts and/or cross-sectional views of the memory device taken along line B-B shown in FIG. 6 during various fabrication stages in the method of FIG. 4, according to one or more aspects of the present disclosure.

FIGS. 11C, 12C, 13C, 14C, 15C illustrate fragmentary layouts and/or cross-sectional views of the memory device taken along line C-C shown in FIG. 6 during various fabrication stages in the method of FIG. 4, according to one or more aspects of the present disclosure.

FIG. 16 illustrates a dopant concentration profile of a doped region over a range of depths in source/drain features, according to one or more aspects of the present disclosure.

FIG. 19 illustrates a flow chart of a method for forming a first alternative memory device including the SRAM cell, according to one or more aspects of the present disclosure.

FIG. 20 illustrates a fragmentary layout of the first alternative memory device, according to one or more aspects of the present disclosure.

FIGS. 21, 22, 23, 24, 25, 26 illustrate fragmentary cross-sectional views of the first alternative memory device taken along line A-A and/or D-D shown in FIG. 20 during various fabrication stages in the method of FIG. 19, according to one or more aspects of the present disclosure.

FIG. 27 illustrates a fragmentary cross-sectional view of a second memory device taken along line A-A, according to one or more aspects of the present disclosure.

FIG. 28 illustrates dopant concentration profiles of a first doped region and a second doped region over a range of depths in source/drain features, according to one or more aspects of the present disclosure.

FIG. 29 illustrates a fragmentary layout of a third alternative memory device, according to one or more aspects of the present disclosure.

FIG. 30 illustrates a fragmentary cross-sectional view of the third memory device taken along line E-E, according to one or more aspects of the present disclosure.

FIG. 31 illustrates a fragmentary cross-sectional view of the third memory device taken along line F-F, according to one or more aspects of the present disclosure.

FIGS. 32 and 33 each illustrate a fragmentary top view of a fourth alternative memory device and a fifth alternative memory device, respectively, according to one or more aspects of the present disclosure.

FIG. 34 illustrates a fragmentary layout of the IC chip, according to one or more aspects of the present disclosure.

FIG. 35 is a circuit diagram of a different memory cell, such as a different SRAM cell, that can be implemented in the IC chip of FIG. 1, according to various aspects of the present disclosure.

FIG. 36 illustrates a fragmentary layout of another memory device including the different memory cell, according to various aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

As the feature sizes continue to decrease, memory devices that include SRAM cells have also begun to adopt nanostructure transistor (e.g., GAA FET) solutions to improve cell performance, e.g., cell current, operation voltage (e.g., Vmax, Vmin, etc.), SRAM margin (e.g., write margin and/or read margin) and/or operation speed. For a compact two-port SRAM cells capable of writing and reading data, read-port pass-gate transistors (R-PGs) and pull-up transistors PU-1 and PU-2 may be formed to over a same active region and have a same channel width. However, if saturation current Isat of the read-port pass-gate transistors (R-PGs) is substantially equal to or greater than saturation current Isat of pull-up transistors PU-1 and PU-2, “alpha ratio” of the saturation current, that is the ratio of Isat of pull-up transistors to Isat of read-port pass-gate transistors (R-PGs), may be too low, leading to a poor read window.

The present disclosure provides memory devices including SRAM cells with high alpha ratio and enlarged read window and improved voltage dynamic data retention V_{ddr}. In an exemplary process, after forming source/drain features of the pull-up transistors PU-1 and PU-2 and the read-port pass-gate transistors (R-PGs), an ion implantation process is performed to selectively form a doped region within the source/drain features of the pull-up transistors PU-1 and PU-2. The formation of the doped region increases dopant concentrations of the source/drain features of the pull-up transistors PU-1 and PU-2 and reduce parasitic resistances, thereby increasing the saturation current Isat of pull-up transistors PU-1 and PU-2. In some embodiments, one of the source/drain feature of the read-port pass-gate transistor (R-PG) also includes a doped region, however, its dopant concentration and depth are less than those of the doped region of the pull-up transistors PU-1 and PU-2. Therefore, alpha ratio can be increased, and read window can be enlarged.

The various aspects of the present disclosure will now be described in more detail with reference to the figures. For avoidance of doubts, the X-axis, Y-axis and Z-axis in the figures are perpendicular to one another and are used consistently throughout the present disclosure. Throughout the present disclosure, like reference numerals denote like features unless otherwise excepted.

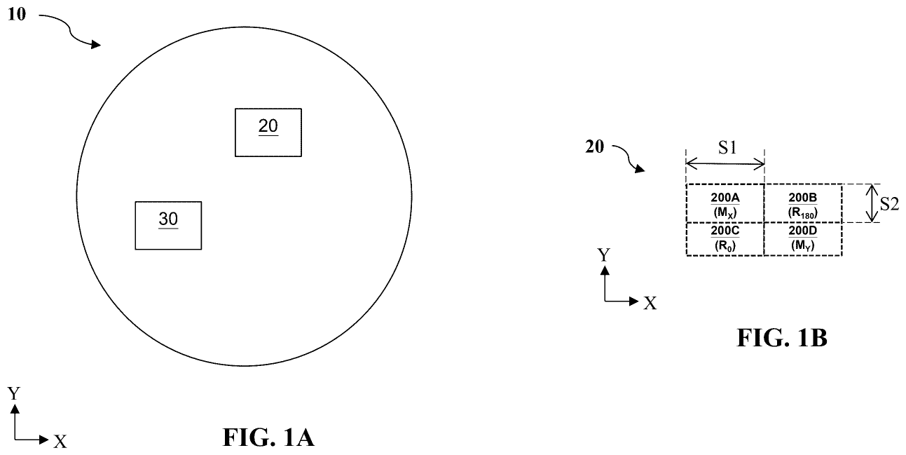

Referring to FIG. 1A, the present disclosure provides an IC chip 10 formed over a substrate and includes at least an array 20 of memory cells. The array 20 may include static random-access memory (SRAM) cells, dynamic random-access memory (DRAM) cells, non-volatile random-access memory (NVRAM) cells, flash memory cells, other suitable memory cells, or combinations thereof. The IC chip 10 may further include a number of other components, such as an array 30 of standard logic (STD) cells configured to provide various standard logic devices, such as inverter, AND, NAND, OR, XOR, NOR, other suitable devices, or combinations thereof. Additionally, the IC chip 10 may include various passive and active microelectronic devices, such as resistors, capacitors, inductors, diodes, bipolar transistors, high voltage transistors, high frequency transistors, other suitable devices, or combinations thereof. Additional features can be added to the IC chip 10 and some of the features described below can be replaced, modified, or eliminated in other embodiments of the IC chip 10.

In the present embodiments, referring to FIG. 1B, the array 20 includes a number of SRAM cells (such as SRAM cells 200A, 200B, 200C, and 200D), which generally provide memory or storage capable of retaining data when power is applied. As such, the array 20 is hereafter referred to as an SRAM array 20. The array 20 may also be referred to as a memory device 20 or a semiconductor structure 20. In the present disclosure, the memory device 20 may include one or more SRAM cells 200A-200D and frontside and backside interconnect structures associated with the one or more SRAM cells. In the present embodiments, each of the SRAM cells 200A-200D includes one or more GAA transistors to be discussed in detail below.

In the present embodiments, still referring to FIG. 1B, the SRAM cells 200A, 200B, 200C, and 200D, together defining a two-by-two grid, exhibit mirror and/or rotational symmetry with respect to each other. For example, using the SRAM cell 200C as a reference (denoted “R₀”), a layout of the SRAM cell 200A (denoted “M_{X}”) is a mirror image of a layout of the SRAM cell 200C with respect to the X-axis. Similarly, a layout of the SRAM cell 200B is a mirror image of the layout of the SRAM cell 200A, and a layout of the SRAM cell 200D (denoted “M_{Y}”) is a mirror image of the layout of the SRAM cell 200C, both with respect to the Y-axis. In other words, the layout of the SRAM cell 200B (denoted “R₁₈₀”) is symmetric to the layout of the SRAM cell 200C by a rotation of 180 degrees about a geometric center of the grid, which is defined as an intersection point of an imaginary line bisecting the rectangular grid along the Y-axis and an imaginary line bisecting the rectangular grid along the X-axis. Furthermore, in the depicted embodiments, the SRAM cells 200A-200D are substantially the same in size, i.e., having substantially the same horizontal (long) pitch S1 along the X-axis and a vertical (short) pitch S2 along the Y-axis. As such, each of the SRAM cells 200A-200D may hereafter be referred to as the SRAM cell 200 for purposes of simplicity.

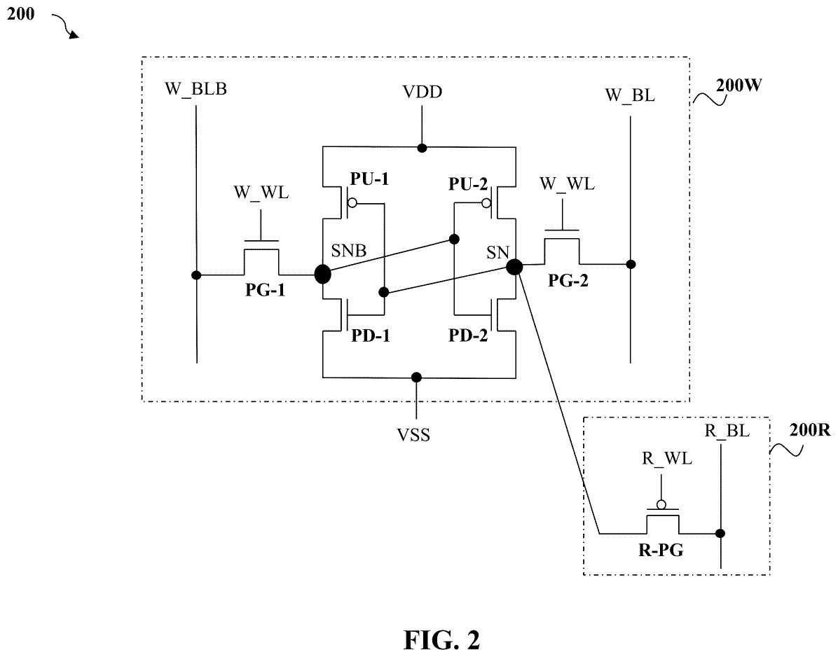

FIG. 2 illustrates an example circuit schematic for a two-port SRAM cell 200 that includes seven transistors (7T). The two-port SRAM cell 200 includes a write port portion 200W. In the present embodiments, the write port portion 200W includes pull-up transistors PU-1, PU-2, pull-down transistors PD-1, PD-2, and pass-gate transistors PG-1, PG-2. In the illustrated embodiment, transistors PU-1 and PU-2 are p-type transistors, and transistors PG-1, PG-2, PD-1, and PD-2 are n-type transistors. The drains of the pull-up transistor PU-1 and the pull-down transistor PD-1 are coupled together, and the drains of the pull-up transistor PU-2 and the pull-down transistor PD-2 are coupled together. The transistors PU-1 and PD-1 are cross-coupled with the transistors PU-2 and PD-2 to form a data latch. The gates of the transistors PU-1 and PD-1 are coupled together and to the common drains of the transistors PU-2 and PD-2 to form a storage node SN, and the gates of the transistors PU-2 and PD-2 are coupled together and to the common drains of the transistors PU-1 and PD-1 to form a complementary storage node SNB. Sources of the pull-up transistors PU-1 and PU-2 are coupled to a power line configured to provide a first voltage VDD (this power line may be referred to as a VDD line), and the sources of the pull-down transistors PD-1 and PD-2 are coupled to a power line configured to provide a second voltage VSS (this power line may be referred to as a VSS line), which may be an electrical ground in some embodiments.

The storage node SN of the data latch is coupled to a bit line W_BL of the write port portion 200W (may be referred to as a write bit line W_BL or a write-port bit line W_BL) through the pass-gate transistor PG-2, and the complementary storage node SNB is coupled to a complementary bit line W_BLB of the write port portion 200W (may be referred to as a complementary write bit line W_BLB or a complementary write-port bit line W_BLB) through the pass-gate transistor PG-1. The storage node SN and the complementary storage node SNB are complementary nodes that are often at opposite logic levels (logic high or logic low). Gates of the pass-gate transistors PG-1 and PG-2 are coupled to a word line W_WL of the write port portion 200W (may be referred to as a write word line W_WL or a write-port word line W_WL).

The two-port SRAM cell 200 also includes a read port portion 200R coupled to the write port portion 200W. The read port portion 200R of the SRAM cell 200 includes a read-port pass-gate transistor R-PG. One source/drain terminal (e.g., a source terminal) of the read-port pass-gate transistor R-PG is electrically coupled to a bit line R_BL of the read port portion 200R. The bit line of the read port portion 200R may be referred to as a read-port bit line R_BL or a read bit line R_BL. The other source/drain terminal (e.g., a drain terminal) of the read-port pass-gate transistor R-PG is electrically coupled to the storage node SN (or to the gates of the transistors PU-1 and PD-1). The gate of the read-port pass-gate transistor R-PG is coupled to a word line R_WL of the read port portion 200R. The word line R_WL of the read port portion 200R may be referred to as a read word line R_WL or a read-port word line R_WL. In the illustrated embodiment, the transistor R-PG is a p-type transistor. That is, in the two-port SRAM cell 200, the pass-gate transistors in the write port portion 200W are n-type transistors, and the pass-gate transistor in read port portion 200R is a p-type transistor.

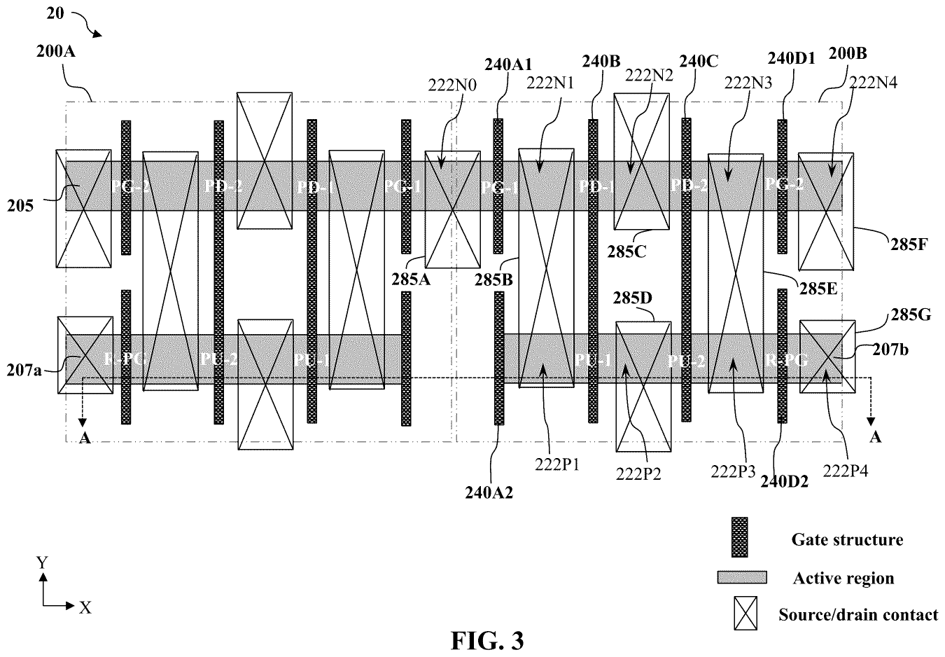

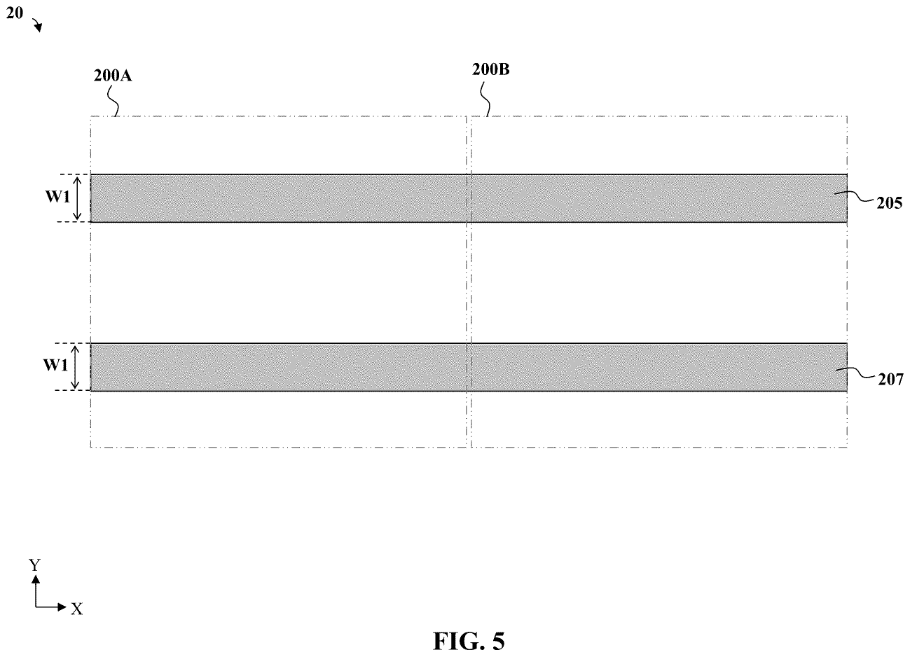

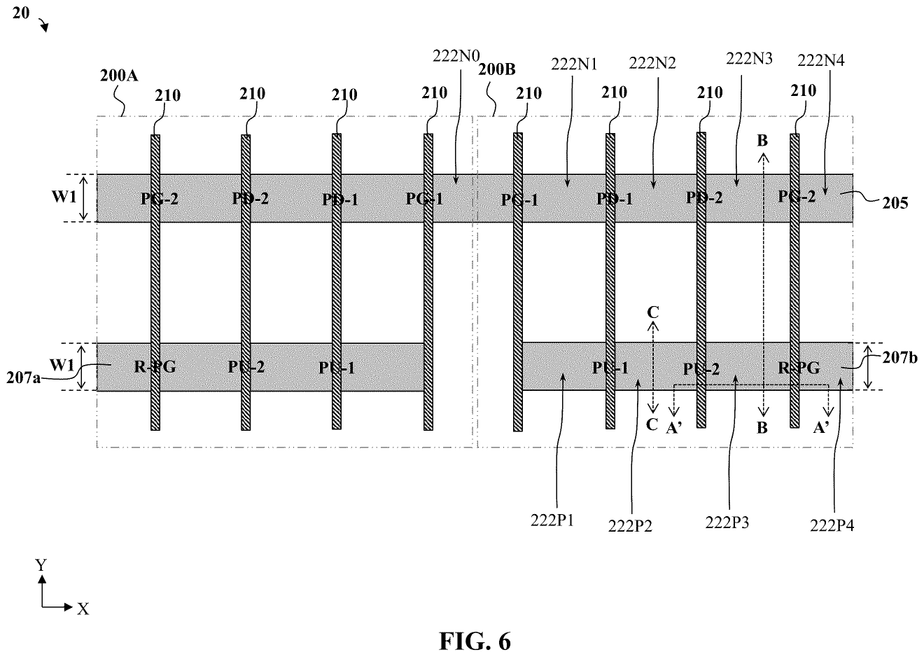

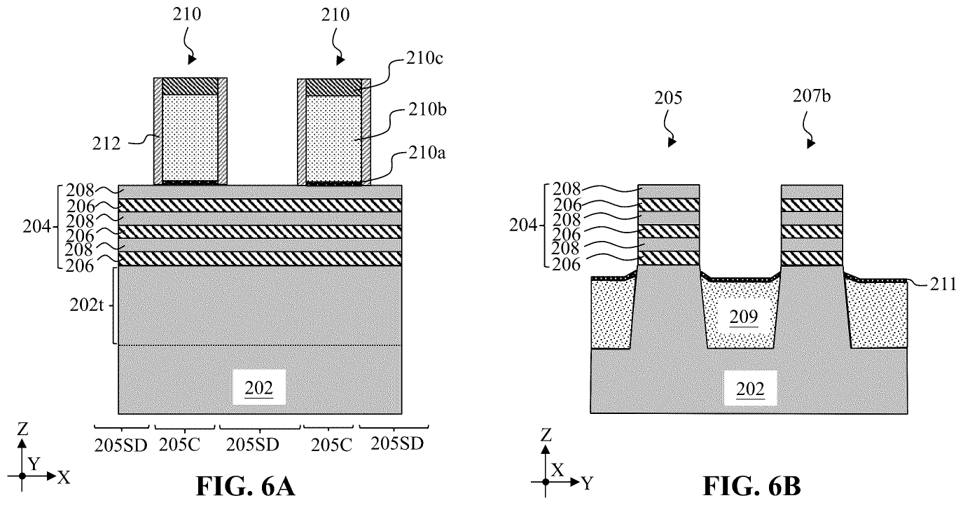

FIG. 3 illustrates a fragmentary layout view of the array 20, in accordance with some embodiments of the present disclosure. In this illustrated embodiment, two SRAM cells 200A and 200B are illustrated, and the layout of the SRAM cell 200A is a mirror image of the layout of the SRAM cell 200B. A boundary of the two-port SRAM cell 200B is illustrated using broken lines. The two-port SRAM cell 200B includes active regions 205 and 207b over a substrate 202. In embodiments presented by FIG. 3, the active regions 205 and 207b each extend lengthwise along the X-axis. They may be spaced apart from each other along the Y-axis by an isolation structure (e.g., shallow trench isolation (STI) features), such as an isolation feature 209 shown in FIG. 6B. In the present embodiments, the active region 205 is a three-dimensional active region disposed over a doped region or well (e.g., P-well, not illustrated) and configured to provide channel regions of N-type transistors, such as a pull-down transistor or a pass-gate transistor, and the active region 207b is a three-dimensional active region disposed in another doped region (e.g., N-well, not illustrated) and configured to provide channel regions of P-type transistors, such as pull-up transistors. The active region 205 extends beyond the boundary of the SRAM cell 200B and extends across the boundary of the SRAM cell 200A. In other words, the SRAM cell 200A and the SRAM cell 200B share a same active region 205. The SRAM cell 200A includes another active region 207a which is a mirror image of the active region 207b of the SRAM cell 200B. The portion of the active region 205 in the SRAM cell 200B includes channel regions formed of nanostructures and N-type source/drain features 222N0-222N4. The active region 207b in the SRAM cell 200B includes channel regions formed of nanostructures and P-type source/drain features 222P1-222P4. The formation of the active regions 205, 207b, 207a will be described in detail with reference to FIGS. 5-6.

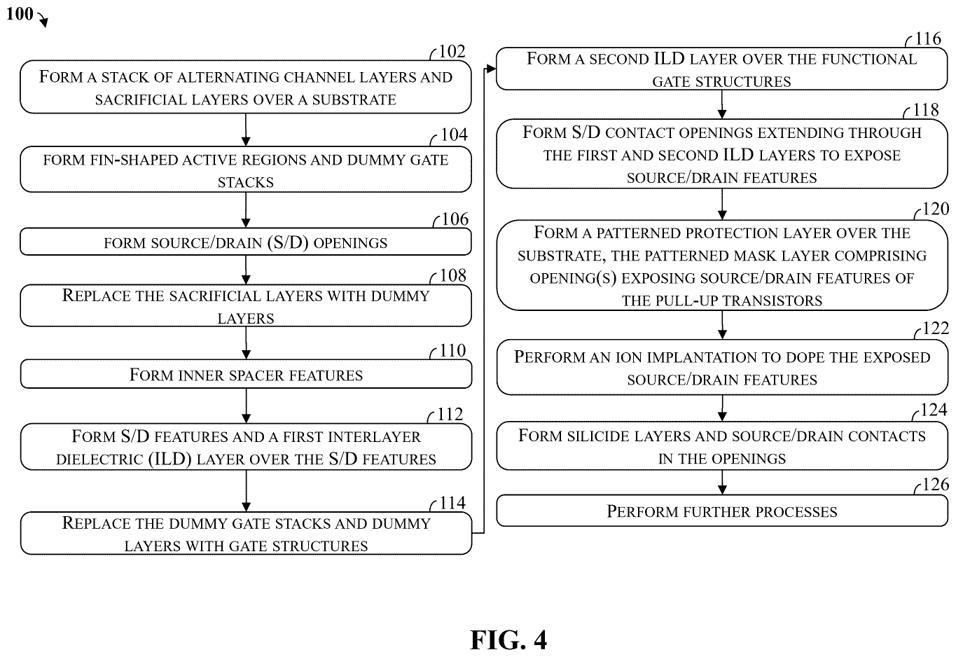

The SRAM cell 200B also includes gate structures, such as gate structures 240A2, 240A1, 240B, 240C, 240D1 and 240D2, oriented lengthwise along the Y-axis and disposed over the active region 205 and/or the active region 207b to form various transistors. Each of the gate structures 240A2, 240A1, 240B, 240C, 240D1 and 240D2 traverses a channel region of the active region 205 and/or a channel region of the active region 207b. In the depicted embodiments, referring to FIG. 4 as an example, the gate structure 240A1 is formed over the active region 205 to form the pass-gate transistor PG-1. The gate structure 240B engages the active region 205 and the active region 207b to form the pull-down transistor PD-1 and the pull-up transistor PU-1, respectively. The gate structure 240C engages the active region 205 and the active region 207b to form the pull-down transistor PD-2 and the pull-up transistor PU-2, respectively. The gate structure 240D1 engages the active region 205 to form the pass-gate transistor PG-2. The gate structure 240D2 engages the active region 207b to form the form the read-port pass-gate transistor R-PG. The gate structure 240A2 is formed at an end of the active region 207b and does not engage with the active region 207b to form a transistor. The gate structures 240A2, 240A1, 240B, 240C, 240D1 and 240D2 may extend beyond the illustrated boundary since these active regions and gate structures may also form components of other adjacently located SRAM cells as well. In an embodiment, the gate structure 240A2 and the gate structure 240A1 are portions of a continuous gate structure similar to the gate structure 240B/240C, the gate structure 240D1 and the gate structure 240D2 are portions of a continuous gate structure similar to the gate structure 240B/240C. To fulfill desired functions, an isolation structure may be formed to cut the continuous gate structure into two electrically and physically isolated portions. That is, sidewalls of the gate structures 240A2 and 240A1 are aligned along the Y-axis, sidewalls of the gate structures 240D1 and 240D2 are aligned along the Y-axis. In the present embodiments, the pull-up transistors PU-1, the PU-2, and the read-port pass-gate transistor R-PG are P-type GAA transistors, and the pull-down transistors PD-1 and PD-2, the pass-gate transistor PG-1, and PG-2 are N-type GAA transistors. The gate structures of the SRAM cell 200A may be a mirror image of gate structures of the SRAM cell 200B, and repeated description is omitted for reason of simplicity.

The array 20 also includes source/drain contacts 285A-285G formed over the SRAM cells 200A and 200B. For example, the SRAM cell 200B includes a source/drain contact 285A landing over and electrically coupled to a source/drain feature 222N0 of the pass-gate transistor PG-1. The source/drain contact 285A may electrically connect the source/drain feature 222N0 of the pass-gate transistor PG-1 to the complementary write-port bit line (W_BLB). The SRAM cell 200B also includes a source/drain contact 285B electrically connecting a common source/drain feature (e.g., a drain feature) 222N1 of the pass-gate transistor PG-1 and the pull-down transistor PD-1 together with a source/drain feature (e.g., a drain feature) 222P1 of the pull-up transistor PU-1 to the complementary storage node (SNB), a source/drain contact 285C electrically connecting a common source/drain feature (e.g., a source feature) 222N2 of the pull-down transistor PD-1 and the pull-down transistor PD-2 to the VSS line, a source/drain contact 285D electrically connecting a common source/drain feature (e.g., a source feature) 222P2 of the pull-up transistor PU-1 and the pull-up transistor PU-2 to the VDD line, a source/drain contact 285E electrically connecting a common source/drain feature (e.g., a drain feature) 222N3 of the pass-gate transistor PG-2 and the pull-down transistor PD-2 together with a common source/drain feature (e.g., a drain feature) 222P3 of the pull-up transistor PU-2 and the read-port pass-gate transistor R-PG to the storage node (SN), a source/drain contact 285F electrically connecting a source/drain feature (e.g., a source feature) 222N4 of the pass-gate transistor PG-2 to the write-port bit line (W_BL), and a source/drain contact 285G electrically connecting a source/drain feature (e.g., a source feature) 222P4 of the read-port pass-gate transistor R-PG to the read-port bit line (R_BL). The source/drain contact 285A is shared by the SRAM cell 200A and the SRAM cell 200B. Besides the source/drain contact 285A, other source/drain contacts of the SRAM cell 200A are a mirror image of the source/drain contacts 285B-285G of the SRAM cell 200B, and repeated description is omitted for reason of simplicity. In the illustrated embodiment, the source/drain contacts 285A-285G each are elongated and have a longitudinal direction in the Y-axis, which is parallel to the extending directions of the gate structures 240A1-240D2. As described above, to improve the performance of the SRAM cells and memory devices, the pull-up transistors PU-1 and/or PU-2 and the read-port pass gate transistor (R-PG) are formed over a same active region, and the pull-up transistors PU-1 and/or PU-2 are configured to have a higher saturation current than that of the read-port pass gate transistor (R-PG). Method for forming the memory device with improved performance is described below with reference to FIGS. 4-18, where FIG. 4 illustrates a flow chart of a method 100 for forming a semiconductor structure (e.g., the memory device) 20, according to one or more aspects of the present disclosure, and FIGS. 5-18 illustrate fragmentary layouts and/or cross-sectional views of the semiconductor structure 20 during various fabrication stages in the method of FIG. 4, according to one or more aspects of the present disclosure.

Referring to FIGS. 4, 5, 6 and 6A-6B, method 100 includes a block 102 where a stack 204 of alternating channel layers and sacrificial layers are formed over a substrate 202. FIG. 5 depicts a top view of a structure 20 including active regions formed from the stack 204. The structure 20 includes a first region 200A for forming the SRAM cell 200A (or “first region 200A”) and a second region for forming the SRAM cell 200B (or “second region 200B”). FIG. 6 depicts a top view of the structure 20 including the active regions and dummy gate stacks. FIG. 6A depicts a fragmentary cross-sectional view of the structure 20 taken along line A′-A′ shown in FIG. 6, and FIG. 6B depicts a fragmentary cross-sectional view of the structure 20 taken along line B-B shown in FIG. 6. The first region 200A is a mirror image of the second region 200B, and for ease of description, the discussion below will focus on the second region 200B.

In one embodiment, the substrate 202 (shown in FIGS. 6A-6B) is a silicon (Si) substrate. In some other embodiments, the substrate 202 may include other semiconductors such as germanium (Ge), silicon germanium (SiGe), or a III-V semiconductor material. Exemplary III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 202 may also include an insulating layer, such as a silicon oxide layer, to have a semiconductor-on-insulator (SOI) structure. Although not explicitly shown in the figures, the substrate 202 may include an n-type well region and a p-type well region for fabrication of transistors of different conductivity types. When present, each of the n-type well and the p-type well is formed in the substrate 202 and includes a doping profile. An n-type well may include a doping profile of an n-type dopant, such as phosphorus (P) or arsenic (As). A p-type well may include a doping profile of a p-type dopant, such as boron (B). The doping in the n-type well and the p-type well may be formed using ion implantation or thermal diffusion and may be considered portions of the substrate 202.

The stack 204 includes a number of sacrificial layers 206 and a number of channel layers 208 interleaved by the number of sacrificial layers 206. The channel layers 208 and the sacrificial layers 206 include different materials to provide etch selectivity. Each channel layer 208 may include a semiconductor material such as, for example, Si, Ge, SiC, SiGe, GeSn, SiGeSn, SiGeCSn, other suitable semiconductor materials, or combinations thereof, while each sacrificial layer 206 has a material different from that of the channel layer 208. In one such example, the channel layers 208 may include elemental Si and the sacrificial layers 206 may include SiGe. The sacrificial layers 206 and channel layers 208 may be deposited using an epitaxial process. Suitable epitaxial processes include vapor-phase epitaxy (VPE), ultra-high vacuum chemical vapor deposition (UHV-CVD), molecular beam epitaxy (MBE), and/or other suitable processes. As shown in FIGS. 6A-6B, the sacrificial layers 206 and the channel layers 208 are deposited alternatingly, one-after-another, to form the stack 204. It is noted that three layers of the sacrificial layers 206 and three layers of the channel layers 208 are alternately and vertically arranged as illustrated in FIGS. 6A-6B, which are for illustrative purposes only and not intended to be limiting beyond what is specifically recited in the claims. It is understood that any number of sacrificial layers and channel layers can be formed in the stack 204. The number of layers depends on the desired number of channels members for the device 20. In some embodiments, the number of the channel layers 208 is between 2 and 10, and the number of the sacrificial layers 206 is between 2 and 10.

Still referring to FIGS. 4, 5-6 and 6A-6B, method 100 includes a block 104 where the stack 204 and a top portion 202t of the substrate 202 are patterned to form active regions 205 and 207 (shown in FIG. 5). To pattern the stack 204, a hard mask layer may be deposited over the stack 204 to form an etch mask. The hard mask layer may be a single layer or a multi-layer. For example, the hard mask layer may include a pad oxide layer and a pad nitride layer disposed over the pad oxide layer. The active regions 205 and 207 may be patterned from the stack 204 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. In some implementations, double-patterning or multi-patterning processes may be used to define active regions that have, for example, pitches smaller than what is otherwise obtainable using a single, direct photolithography process. In this embodiment, the active regions 205 and 207 have a same channel width W1 along the Y direction.

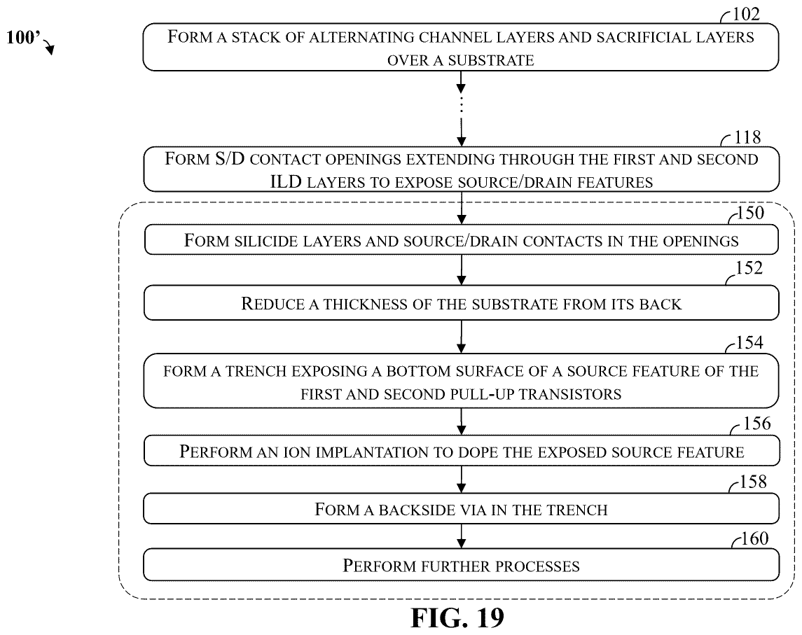

After forming the active regions 205 and 207, a cut-active-region process may be performed to cut the active region 207 into two separated segments 207a and 207b. The segment 207a of the active region 207 (or “active region 207a” is in the first region 200A, and the segment 207b of the active region 207 (or “active region 207b” is in the second region 200B. In an embodiment, the unwanted portion of the active region 207 may be removed by a cut-active-region process that includes a lithography process and an etching process. For example, after the continuous active regions 205 and 207 are formed, a photoresist layer is formed thereon using a spin-coating process and a soft baking process. Then, the photoresist layer is exposed to a radiation using a mask. The exposed photoresist layer is subsequently developed and stripped thereby forming a patterned photoresist layer. The portions of the continuous active region 207 corresponding to the segmented active regions 207a and 207b are protected by the patterned photoresist layer while the unwanted portion therebetween is not protected as such. Subsequently, the unwanted portion is etched through the opening of the patterned photoresist layer. The patterned photoresist layer is removed thereafter using a suitable process, such as wet stripping or plasma ashing. An isolation feature, such as the isolation features 209 shown in FIG. 3 and FIG. 19, is subsequently deposited in the gap between the segmented active regions 207a and 207b. Thus, the isolation between active regions is provided by the isolation feature 209 (e.g., an STI feature) to better safeguard the substrate leakage performance. The isolation feature 209 may include silicon oxide, silicon oxynitride, fluorine-doped silicate glass (FSG), a low-k dielectric, combinations thereof, and/or other suitable materials. In some embodiments, to prevent the isolation feature 209 from being substantially etched during subsequent processes (e.g.,) , a protection layer 211 is formed on the isolation feature 209. For example, the isolation feature 209 may include silicon oxide, and the protection layer 211 may include silicon nitride.

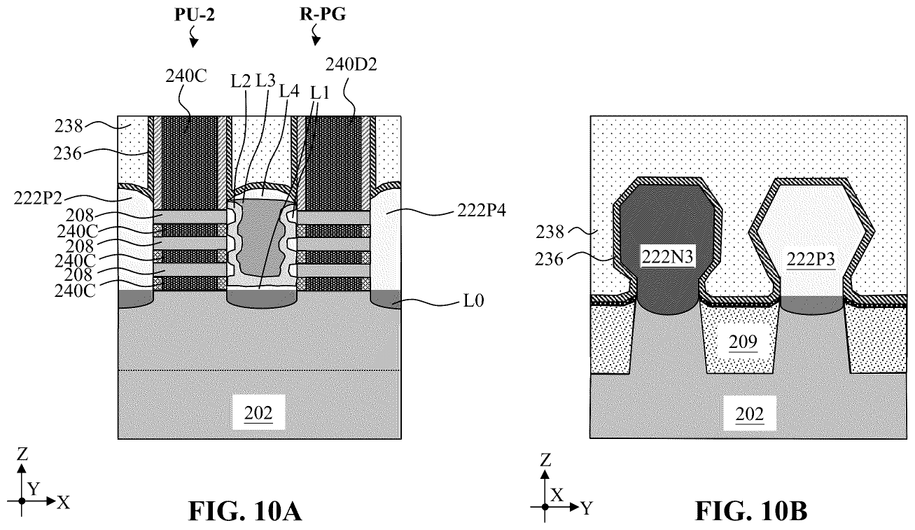

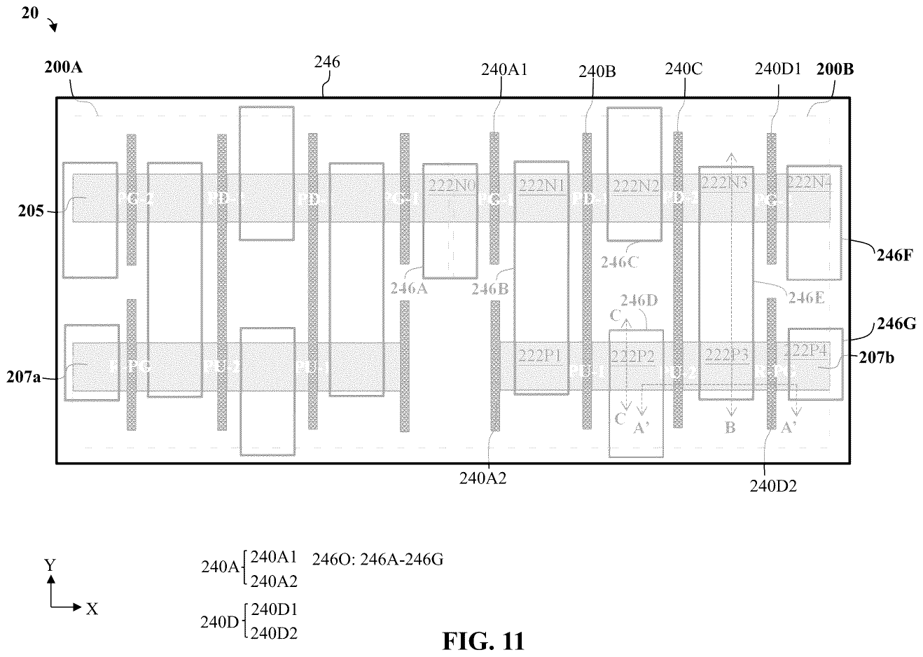

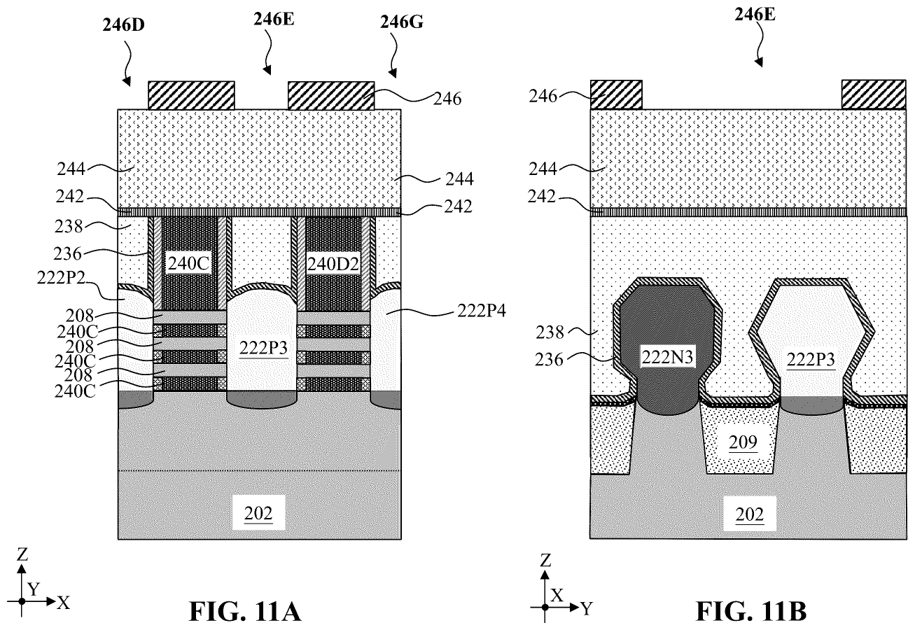

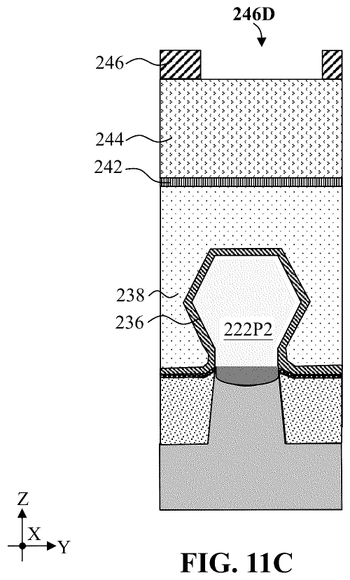

Still referring to FIGS. 4, 6, 6A-6B, operations at the block 104 also include forming dummy gate stacks 210 over channel regions 205C (shown in FIG. 6A) of the active regions 205, 207a, and 207b. The channel regions 205C and the dummy gate stacks 210 also define source/drain regions 205SD (shown in FIG. 6A) that are not vertically overlapped by the dummy gate stacks 210. Each of the channel regions 205C is disposed between two source/drain regions 205SD along the X direction. The dummy gate stack 210 includes a dummy dielectric layer 210a, a dummy gate electrode layer 210b over the dummy dielectric layer 210a, and a gate-top hard mask layer 210c over the dummy gate electrode layer 210b. The dummy dielectric layer 210a may include silicon oxide. The dummy gate electrode layer 210b may include polysilicon. The gate-top hard mask layer 210c may be a multi-layer that includes a silicon oxide layer and silicon nitride layer formed on the silicon oxide layer. Suitable deposition process, photolithography and etching process may be employed to form the dummy gate stack 210. In this embodiment, a gate replacement process (or gate-last process) is adopted where the dummy gate stacks 210 serve as placeholders for gate structures 240 (shown in FIGS. 10A and 11). Other processes and configuration are possible.

Gate spacers 212 are formed to extend along sidewall surfaces of the dummy gate stacks 210. In an example process, the formation of the gate spacers 212 includes conformally depositing a single-layer or a multi-layer dielectric layer (not shown) over the structure 20 and etching back of the dielectric layer from top-facing surfaces of the structure 20 by an anisotropic etch process. The dielectric layer is deposited using chemical vaper deposition (CVD), atomic layer deposition (ALD), or sub-atmospheric chemical vaper deposition (SACVD), and may include silicon oxide, silicon nitride, silicon carbide, silicon oxynitride, silicon carbonitride, silicon oxycarbide, silicon oxycarbonitride, and/or combinations thereof. The term “conformally” may be used herein for ease of description of a layer having a substantially uniform thickness over various regions. The profile of the gate spacer 212 shown in FIG. 6A is just an example and is not intended to be limiting. For example, in some embodiments, the gate spacer 212 may have a non-uniform width from bottom to top, and a top surface of the gate spacer 212 may be lower than a top surface of the dummy gate stack 210. Although not shown, in some embodiments, the formation of the gate spacer 212 may also form fin sidewall spacers directly over the isolation features 209 and extending along lower portions of the active regions 205 and 207a-207b.

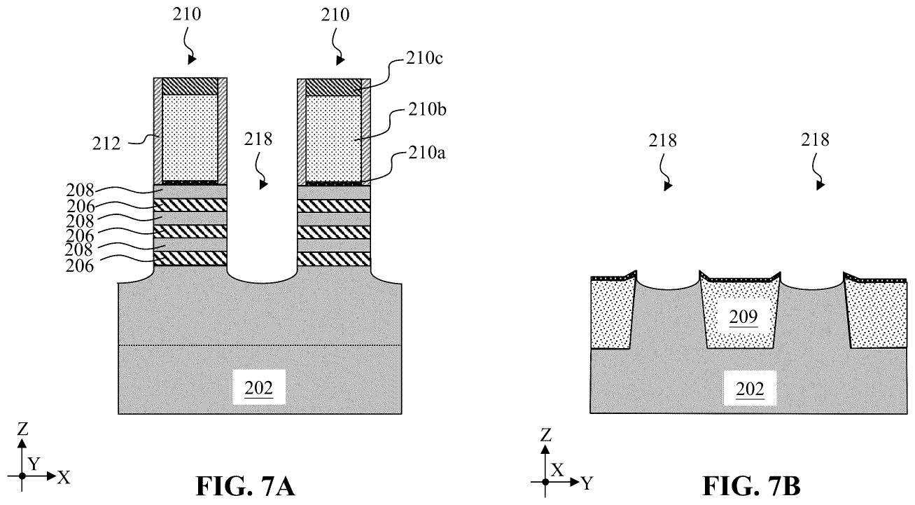

Referring to FIGS. 4 and 7A-7B, method 100 includes a block 106 where source/drain regions 205SD of the active regions 205 and 207a-207b are recessed to form source/drain openings 218. In some embodiments, the source/drain regions 205SD of the active region 205 that are not covered by the dummy gate stacks 210 and the gate spacers 212 are anisotropically etched by a dry etch or a suitable etching process to form source/drain openings 218. An exemplary dry etching process may implement an oxygen-containing gas, hydrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. The source/drain openings 218 extend through the stack 204 of channel layers 208 and sacrificial layers 206 and partially extend into the substrate 202. As illustrated by FIG. 7A, sidewalls of the channel layers 208 and the sacrificial layers 206 are exposed in the source/drain openings 218.

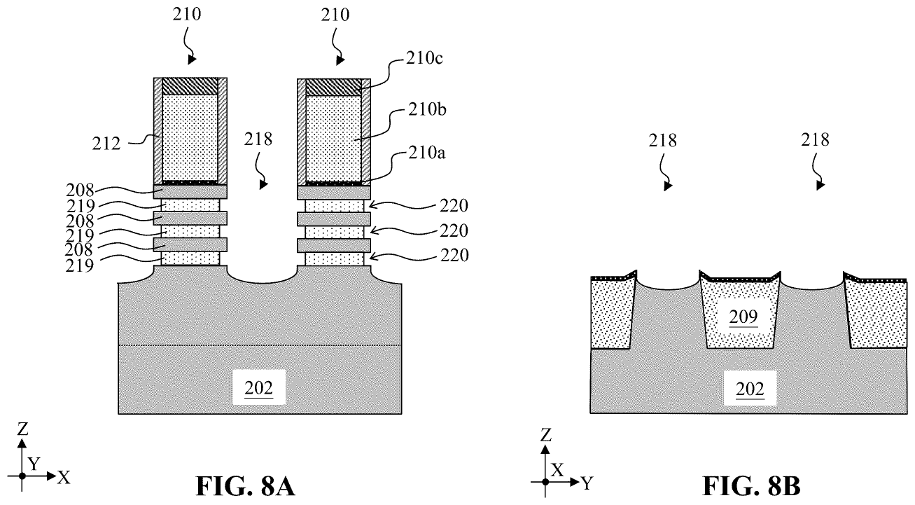

Referring to FIGS. 4 and 8A-8B, method 100 includes a block 108 where the sacrificial layers 206 are replaced with dummy layers. After the formation of the source/drain openings 218, the sacrificial layers 206 interleaving the channel layers 208 in the channel region 205C are selectively removed. The selective removal of the sacrificial layers 206 releases the channel layers 208 to form channel members 208. Depending on the design, the channel members 208 may take form of nanowires, nanosheets, or other nanostructures. The selective removal of the sacrificial layers 206 forms spaces between and around adjacent channel members 208. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

After the selective removal of the sacrificial layers 206, a dielectric material layer is deposited around the channel members 208 and over the source/drain openings 218 to fill the spaces among the channel members 208. The dielectric material layer may include silicon oxide, silicon nitride, silicon oxynitride, silicon carbonitride, silicon oxycarbonitride, high-K dielectric materials (e.g., aluminum oxide, hafnium oxide), other suitable materials, or combinations thereof and may be deposited using plasma enhanced chemical vapor deposition (PECVD) or ALD or other suitable methods. In an embodiment, the dielectric material layer includes silicon oxide. In an embodiment, the dielectric material layer extends conformally over the substrate 202. After the deposition of the dielectric material layer, an etching process is performed to selectively etch the dielectric material layer, thereby forming the dummy layers 219 interleaved by the channel members 208. The etching process may further laterally etch the dummy layers 219, thereby forming inner spacer recesses 220.

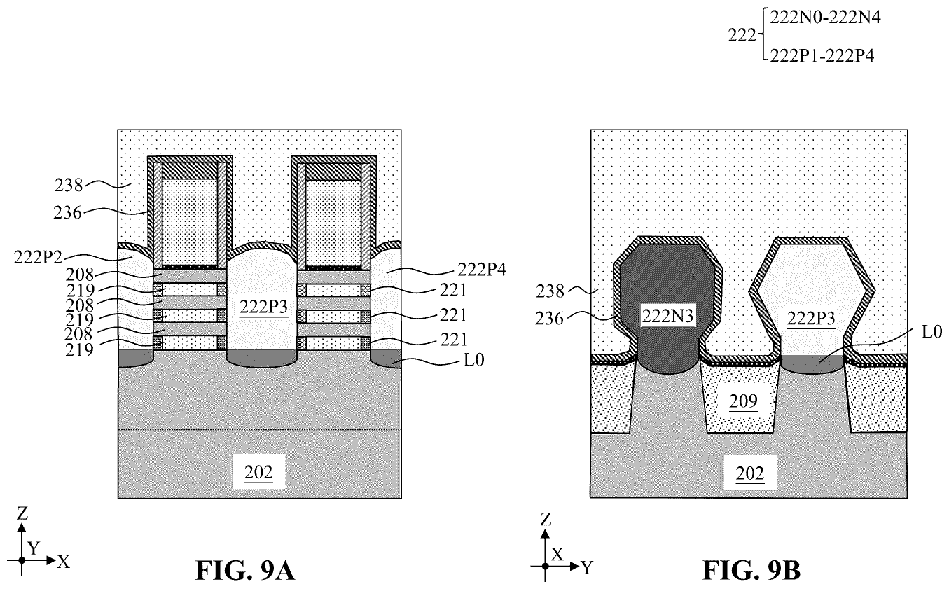

Referring to FIGS. 4 and 9A-9B, method 100 includes a block 110 where inner spacer features 221 are formed. After forming the dummy layers 219 and inner spacer recesses 220, an inner spacer material layer (not shown) is deposited over the structure 20, including in the inner spacer recesses 220. The inner spacer material layer may include silicon oxide, silicon nitride, silicon oxycarbide, silicon oxycarbonitride, silicon carbonitride, metal nitride, or a suitable dielectric material. The deposited inner spacer material layer is then etched back to remove excessive inner spacer material layer, thereby forming the inner spacer features 221.

Still referring to FIGS. 4 and 9A-9B, method 100 includes a block 112 where an undoped semiconductor layer L0 is formed in the lower portion of the source/drain opening 218 and a source/drain feature 222 formed over the undoped semiconductor layer L0 and in the upper portion of the source/drain opening 218. In the present embodiments, after forming the inner spacer features 221, a semiconductor layer L0 (shown in FIG. 9A) is formed over a top surface of the substrate 202 exposed in the source/drain openings 218 by using an epitaxial process. The semiconductor layer L0 may be undoped or not intentionally doped and may include undoped silicon (Si), undoped germanium (Ge), undoped silicon germanium (SiGe), or other suitable materials. In an embodiment, the semiconductor layer L0 includes undoped silicon (Si). Although the semiconductor layer L0 is only illustrated in regions for forming p-type transistors (e.g., pull-up transistors PU-1 and PU-2 and read-port pass gate transistors R-PG), it is understood that the semiconductor layer L0 may also be formed in regions for forming n-type transistors (e.g., pull-down transistors PD-1 and PD2 and pass gate transistors PG-1 and PG-2),

After forming the semiconductor layers L0, source/drain features 222 are formed in the source/drain openings 218 and over the semiconductor layer L0. Source/drain feature(s) may refer to a source or a drain, individually or collectively dependent upon the context. The source/drain features 222 are coupled to the channel members 208 of the channel regions 205C and each may be epitaxially and selectively formed from exposed semiconductor surfaces (e.g., sidewalls of the channel members 208 and top surfaces of the semiconductor layers L0) by using an epitaxial process, such as vapor phase epitaxy (VPE), ultrahigh vacuum chemical vapor deposition (UHV-CVD), molecular-beam epitaxy (MBE), and/or other suitable processes.

The source/drain features 222 include N-type source/drain features such as N-type source/drain features 222N0, 222N1, 222N2, 222N3, 222N4 formed in the second region 200B for forming pull-down transistors PD-1 and PD-2 and the pass-gate transistors PG-1 and PG-2 of the SRAM cell 200B. Example N-type source/drain features may include silicon, phosphorus-doped silicon, arsenic-doped silicon, antimony-doped silicon, or other suitable material and may be in-situ doped during the epitaxial process by introducing an N-type dopant, such as phosphorus, arsenic, or antimony, or ex-situ doped using a junction implant process.

The source/drain features 222 also include P-type source/drain features such as P-type source/drain features 222P1, 222P2 , 222P3, 222P4 formed in the second region 200B for forming pull-up transistors PU-1 and PU-2 and the read-port pass gate transistor R-PG of the SRAM cell 200B. Example P-type source/drain features may include germanium, gallium-doped silicon germanium, boron-doped silicon germanium, or other suitable material and may be in-situ doped during the epitaxial process by introducing a P-type dopant, such as boron or gallium, or ex-situ doped using a junction implant process. In some embodiments, each of the source/drain features 222 may include multiple doped semiconductor layers L1, L2, L3, L4 (illustrated in FIG. 10A) with different doping concentrations. In an embodiment, dopant of the P-type source/drain features 222P1, 222P2, 222P3, 222P4 includes boron, such as a combination of Boron-10 isotope and Boron-11 isotope. B-11 and 11B may be used interchangeably to designate the Boron-11 isotope. B-10 and 10B may be used interchangeably to designate a Boron-10 isotope. B-10 and B-11 are different isotopes of Boron and each has five protons. However, the isotope B-10 has five neutrons, but the isotope B-11 has six neutrons. In an embodiment, in each of the P-type source/drain features 222P1, 222P2, 222P3 and 222P4, 10B and 11B exist in an approximately 20%/80% split (about 20% ¹⁰B and about 80% ¹¹B).

Still referring to FIGS. 4 and 9A-9B, operations at the block 112 also include forming a first interlayer dielectric (ILD) layer 238 over the source/drain features 222. After forming the source/drain features 222, a contact etch stop layer (CESL) 236 and an interlayer dielectric (ILD) layer 238 are deposited over the structure 20. The CESL 236 may include silicon nitride, silicon oxynitride, and/or other materials known in the art and may be formed by ALD, plasma-enhanced chemical vapor deposition (PECVD) process and/or other suitable deposition or oxidation processes. As shown in FIG. 9a, the CESL 236 may be deposited on top surfaces of the source/drain features 222, and sidewalls of the gate spacers 212. The ILD layer 238 is deposited by a PECVD process or other suitable deposition technique over the structure 20 after the deposition of the CESL 236. The ILD layer 238 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, after formation of the ILD layer 238, the structure 20 may be annealed to improve integrity of the ILD layer 238.

Referring to FIGS. 4 and 10A-10B, method 100 includes a block 114 where the dummy gate stacks 210 and the dummy layers 219 are replaced by gate structures 240. A planarization process, such a chemical mechanical polishing (CMP) process is be performed to the structure 20 to remove excessive materials and expose the dummy gate electrode layer 210b in the dummy gate stacks 210. With the exposure of the dummy gate electrode layer 210b, the dummy gate stacks 210 are selectively removed to form gate trenches (now filled by outer portions of the gate structures 240). The removal of the dummy gate stacks 210 may include one or more etching process that are selective to the material in the dummy gate stacks 210. For example, the removal of the dummy gate stacks 210 may be performed using a selective wet etch, a selective dry etch, or a combination thereof. After the removal of the dummy gate stacks 210, the dummy layers 219 are selectively removed to form gate openings (now filled by inner portions of the gate structures 240). The selective removal of the dummy layers may be implemented by a selective dry etch, a selective wet etch, or other selective etching process. An example selective wet etch process may include use of diluted hydrofluoric acid (DHF) or a mixture of hydrofluoric acid (HF) and, ammonium fluoride (NH₄F). An example selective dry etch process may include use of fluoride (F₂) vapor, anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. In some embodiments, the selective wet etching includes an APM etch (e.g., ammonia hydroxide-hydrogen peroxide-water mixture).

The gate structures 240 are then formed in the gate trenches and gate openings. After the release of the channel member 208, the gate structures 240 are each formed to wrap around each of the channel members 208 as shown in FIG. 10A. While not explicitly shown, each of the gate structures 240 includes a gate dielectric layer (not separately labeled) and a gate electrode layer (not separately labeled) over the gate dielectric layer. In some embodiments, the gate dielectric layer includes an interfacial layer disposed on the channel members 208 and a high-k dielectric layer over the interfacial layer. Here, a high-k dielectric layer refers to a dielectric material having a dielectric constant greater than that of silicon dioxide, which is about 3.9. A low-k dielectric layer refers to a dielectric material having a dielectric constant no greater than that of silicon dioxide. In some embodiments, the interfacial layer includes silicon oxide. The high-k dielectric layer is then deposited over the interfacial layer using ALD, CVD, and/or other suitable methods. The high-k dielectric layer may include hafnium oxide. Alternatively, the high-k dielectric layer may include other high-k dielectrics, such as titanium oxide, hafnium zirconium oxide, tantalum oxide, hafnium silicon oxide, zirconium silicon oxide, lanthanum oxide, aluminum oxide, yttrium oxide, SrTiO₃, BaTiO₃, BaZrO, hafnium lanthanum oxide, lanthanum silicon oxide, aluminum silicon oxide, hafnium tantalum oxide, hafnium titanium oxide, (Ba, Sr)TiO₃ (BST), silicon nitride, silicon oxynitride, combinations thereof, or other suitable material. The gate electrode layer is then deposited over the gate dielectric layer using ALD, PVD, CVD, e-beam evaporation, or other suitable methods. The gate electrode layer may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride, titanium aluminum, titanium aluminum nitride, tantalum nitride, tantalum aluminum, tantalum aluminum nitride, tantalum aluminum carbide, tantalum carbonitride, aluminum, tungsten, nickel, titanium, ruthenium, cobalt, platinum, tantalum carbide, tantalum silicon nitride, copper, other refractory metals, or other suitable metal materials or a combination thereof. Further, where the structure 20 includes n-type transistors and p-type transistors, different gate electrode layers may be formed separately for n-type transistors and p-type transistors, which may include different work function metal layers (e.g., for providing different n-type and p-type work function metal layers).

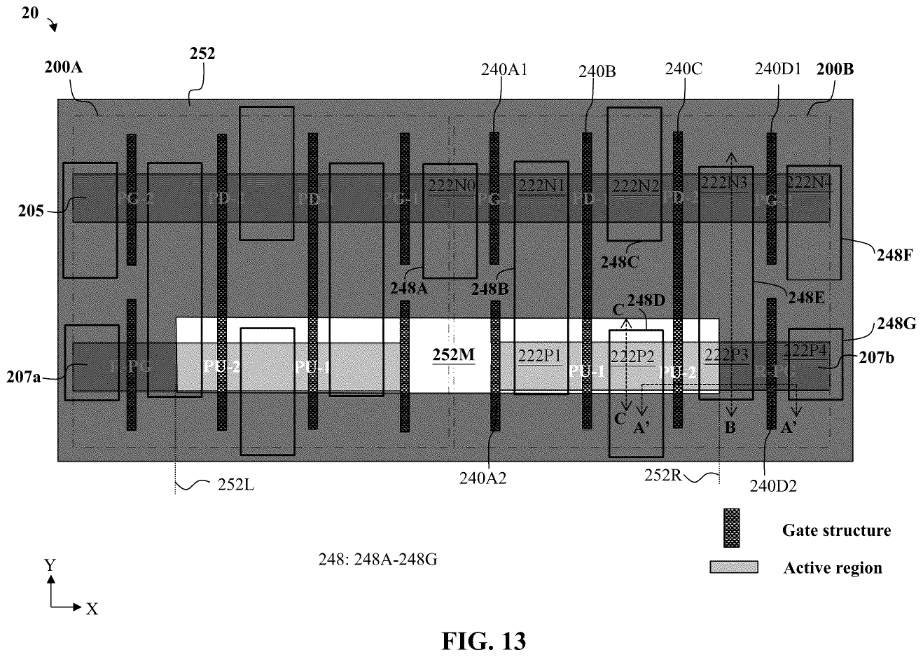

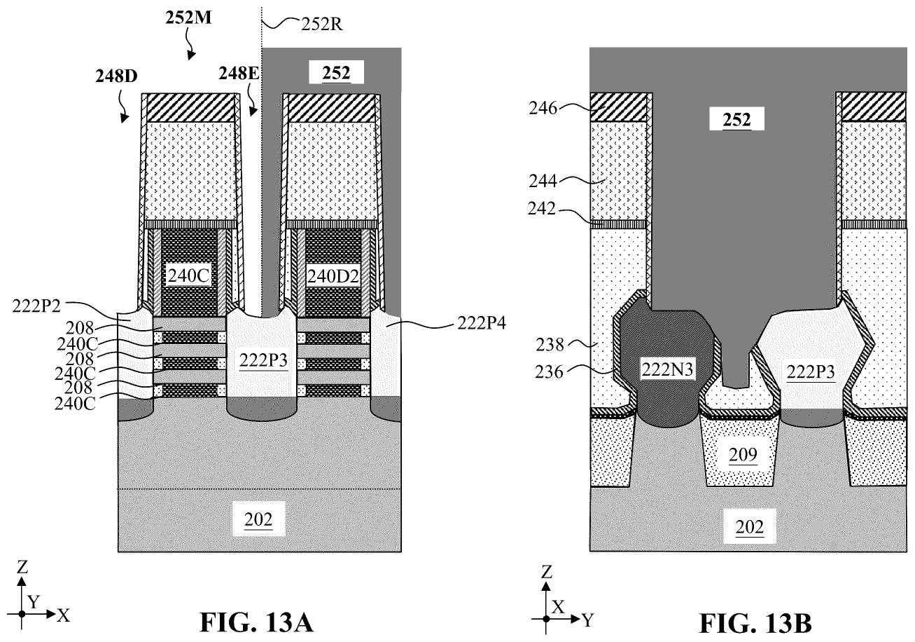

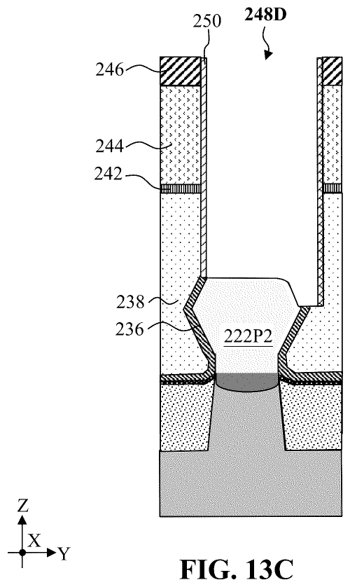

The gate structures 240 include gate structures 240A, 240B, 240C and 240D in the first region for forming SRAM cell 200A and gate structures 240A, 240B, 240C and 240D in the second region for forming SRAM cell 200B. The gate structure 240A includes two segments 240A1 and 240A2 (or “gate structure 240A1”, “gate structure 240A2”), and the gate structure 240D includes two segments 240D1 and 240D2 (or “gate structure 240D1”, “gate structure 240D2”). Gate isolation structures may be formed before or after the formation of the gate structures 240 to cut some of the gate structures 240 (e.g., 240A and 240D) into segments to fulfill desired functions. As represented by FIG. 13, the pass-gate transistor PG-1 includes the gate structure 240A1 and the N-type source/drain features 222N0 and 222N1, the pass-gate transistor PG-2 includes the gate structure 240D1 and the N-type source/drain features 222N3 and 222N4, the pull-down transistor PD-1 includes the gate structure 240B and the N-type source/drain features 222N1 and 222N2, and the pull-down transistor PD-2 includes the gate structure 240C and the N-type source/drain features 222N2 and 222N3. The pull-up transistor PU-1 includes the gate structure 240A2 and the P-type source/drain features 222P1 and 222P2, the pull-up transistor PU-2 includes the gate structure 240C and the P-type source/drain features 222P2 and 222P3, and the read-port pass gate transistor R-PG includes the gate structure 240D2 and the P-type source/drain features 222P3 and 222P4. In the above embodiments, the formation of the gate structures 240A, 240B, 240C and 240D includes selectively removing the sacrificial layers 206 to form gate openings, forming dummy layers 219 in the gate openings, and forming the gate structures 240A, 240B, 240C and 240D in the gate openings. In some other embodiments, the formation of the gate structures 240A, 240B, 240C and 240D does not include the forming and the removing of the dummy layers 219. For example, the formation of the gate structures 240A, 240B, 240C and 240D includes, after forming source/drain features 222, selectively removing the sacrificial layers 206 to form gate openings, and forming the gate structures 240A, 240B, 240C and 240D in the gate openings. Performance of p-type transistors whose formation involves the forming and removing of dummy layers 219 may be improved by about 5% to about 15% compared to performance of p-type transistors whose formation does not involve the forming and removing of dummy layers 219 Referring to FIGS. 4, 11, and 11A-11C, method 100 includes a block 118 where a second interlayer dielectric (ILD) layer 244 is formed over the substrate 202. FIG. 11 depicts a fragmentary and simplified top view of the structure 20, FIG. 11A depicts a fragmentary cross-sectional view of the structure 20 taken along line A′-A′ shown in FIG. 11, FIG. 11B depicts a fragmentary cross-sectional view of the structure 20 taken along line B-B shown in FIG. 11, FIG. 11C depicts a fragmentary cross-sectional view of the structure 20 taken along line C-C shown in FIG. 11. After forming the metal gate structures 240, an etch stop layer 242 is formed over the first interlayer dielectric (ILD) layer 238. The etch stop layer 242 may include silicon nitride, silicon oxynitride, and/or other suitable materials and may be formed by ALD, plasma-enhanced chemical vapor deposition (PECVD) process and/or other suitable deposition or oxidation processes. The formation of the etch stop layer 242 may facilitate the formation of gate vias over the metal gate structures 240 during subsequent fabrication process. The second ILD layer 244 is deposited over the etch stop layer 242 by a PECVD process or other suitable deposition technique over the structure 20. The second ILD layer 244 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

Referring now to FIGS. 4, 11, 11A-11C, 12, and 12A-12C method 100 includes a block 118 where source/drain contact openings 248 are each formed to expose one or more source/drain features 222. In this illustrated embodiments, as represented by FIGS. 11 and 11A-11C, a patterned mask 246 is formed over the structure 20. The patterned mask 246 may include silicon nitride, silicon oxynitride, silicon carbonitride, or other suitable dielectric material. In an exemplary process for forming the patterned mask 246, a hard mask layer may be deposited using chemical vapor deposition (CVD), atomic layer deposition (ALD), or other suitable deposition technique. A photoresist layer may be then deposited over the hard mask layer using spin-on coating, CVD, or other similar processes. The photoresist layer is baked in a pre-exposure baking process, exposed to a radiation source reflected from or transmitting through a photomask with pattern, baked in a post-exposure baking process and developed in a developing process. Because the photoresist layer is selected to be sensitive to the radiation, exposed (or non-exposed) portions of the photoresist layer undergo chemical changes to become soluble in a developer solution during a subsequent developing process. The patterned photoresist layer carries pattern that corresponds to the pattern of the photomask. While using the patterned photoresist layer as an etch mask, the hard mask layer is etched to form the patterned mask 246. In this illustrated embodiment, the patterned mask 246 includes a number of openings (e.g., openings 246A, 246B, 246C, 246D, 246E, 246F, 246G in the second region 200B) disposed directly over the source/drain features 222. In particular, in the second region 200B, the opening 246A is disposed directly over the source/drain feature 222N0, the opening 246B is disposed directly over the source/drain features 222N1 and 222P1, the opening 246C is disposed directly over the source/drain feature 222N2, the opening 246D is disposed directly over the source/drain feature 222P2, the opening 246E is disposed directly over the source/drain features 222N3 and 222P3, the opening 246F is disposed directly over the source/drain feature 222N4, and the opening 246G is disposed directly over the source/drain feature 222P4. One or more of the openings 246A-246G may be separately or collectively referred to as opening(s) 246O. After forming the patterned mask 246, the photoresist layer is selectively removed.

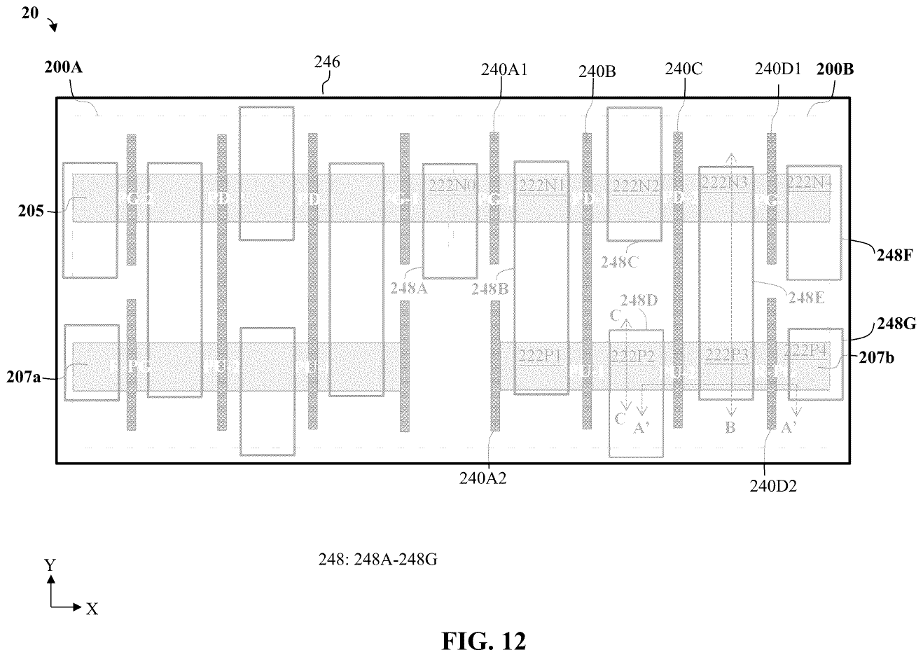

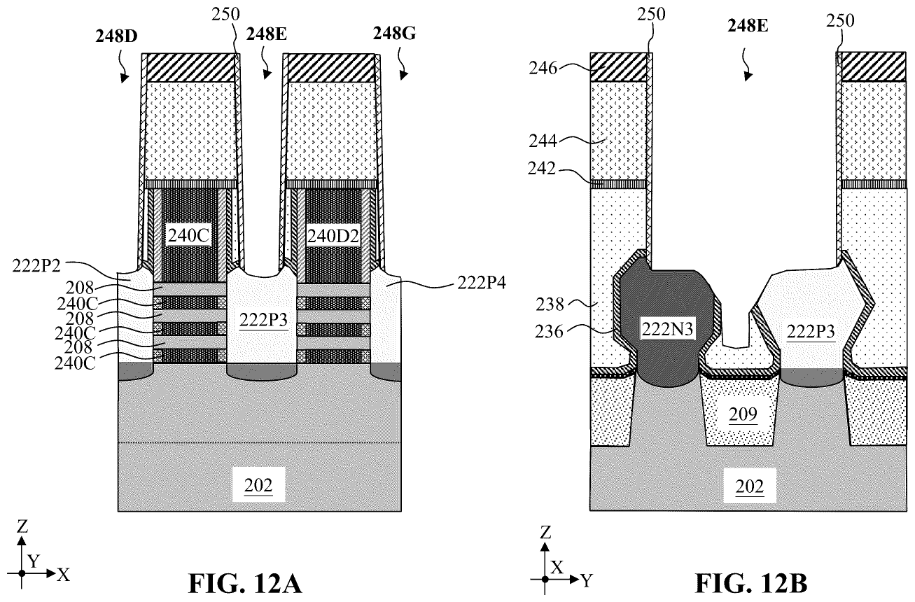

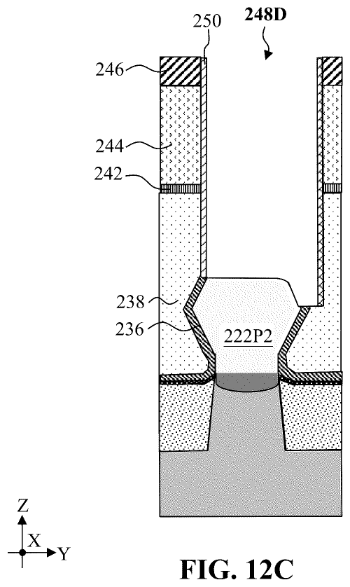

With reference to FIGS. 12 and 12A-12C, while using the patterned mask 246 as an etch mask, an etching process is performed to remove portions of the dielectric layers (e.g., CESL 236, first ILD layer 238, etch step layer 242, and second ILD layer 244) to form S/D contact openings 248 under the openings 246O. The etching process may be a dry etch process that includes use of argon (Ar), a fluorine-containing etchant (for example, SF₆, NF₃, CH₂F₂, CHF₃, C₄F₈, and/or C₂F₆), an oxygen-containing etchant, a chlorine-containing etchant (for example, Cl₂, CHCl₃, CCl₄, and/or BCl₃), a bromine-containing etchant (for example, HBr and/or CHBr₃), an iodine-containing etchant, or combinations thereof. Each of the S/D contact openings 248 exposes one or more source/drain features disposed directly under the corresponding openings 246O. More specifically, the S/D contact openings 248A, 248B, 248C, 248D, 248E, 248F, and 248G are formed under the openings 246A, 246B, 246C, 246D, 246E, 246F, and 246G, respectively. One or more of the S/D contact openings 248A-248G may be separately or collectively referred to as S/D contact opening(s) 248. In some embodiments, after forming the S/D contact opening 248, a dielectric liner 250 is formed over the substrate 202 and extends along sidewalls of the S/D contact opening 248. The dielectric liner 250 may include silicon nitride, silicon oxide, silicon oxycarbide (SiOC), silicon oxycarbonitride (SiOCN) or other suitable materials.

Referring now to FIGS. 4, 13, and 13A-13C, method 100 includes a block 120 where a patterned protection layer 252 is formed over the substrate 202. FIG. 13 depicts a fragmentary top view of the structure 20 having the patterned protection layer 252. FIG. 13A depicts a fragmentary cross-sectional view of the structure 20 taken along line A′-A′ shown in FIG. 13, FIG. 13B depicts a fragmentary cross-sectional view of the structure 20 taken along line B-B shown in FIG. 13, and FIG. 13C depicts a fragmentary cross-sectional view of the structure 20 taken along line C-C shown in FIG. 13.

In an embodiment, the patterned protection layer 252 may include a photoresist layer and may be formed by a combination of photolithography process (e.g., coating, pre-exposure baking, exposure, post-exposure baking process, developing process). The patterned protection layer 252 includes one or more openings (e.g., 252M shown in FIG. 13) configured to define regions that will undergo a subsequent ion implantation process while other regions are protected by the patterned protection layer 252. As described above, the pull-up transistors PU-1 and PU-2 are configured such that they have a higher saturation current than the read-port pass gate transistor RPG. In the present disclosure, to obtain a higher alpha ratio, an ion implantation process is performed to further dope the source/drain features of the pull-up transistors PU-1 and PU-2 without doping source/drain features (e.g., 222N0-222N4, 222P4) of other transistors. In addition, since the pull-up transistor PU-2 and the read-port pass gate transistor R-PG share a source/drain feature 222P3, only a part of the source/drain feature 222P3 closer to the gate structure 240C of the pull-up transistor PU-2 is doped by the ion implantation process, and the other part of the source/drain feature 222P3 closer to the gate structure 240D2 of the read-port pass gate transistor R-PG is not doped by the ion implantation process. In this embodiment, a right boundary 252R (shown in FIGS. 13 and 13A) of the opening 252M directly over the source/drain feature 222P3 is aligned with a center line of the source/drain feature 222P3, and a left boundary 252L (shown in FIG. 13) of the opening 252M is directly over the adjacent SRAM cell 200A. As represented by FIGS. 13 and 13A-13C, in the second region 200B, the opening 252M exposes the source/drain contact opening 248B over the source/drain feature 222P1, the source/drain contact opening 248D over the source/drain feature 222P2, and a part of the source/drain contact opening 248E over the source/drain feature 222P3. The situation in the first region 200A is a mirror image of the second region 200B and repeated description is omitted for reason of simplicity.

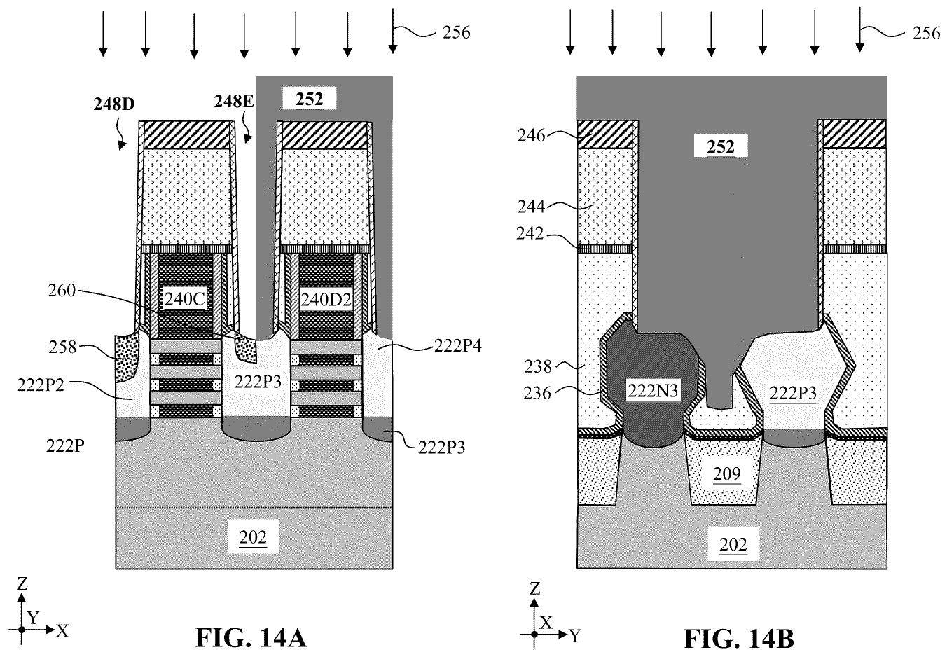

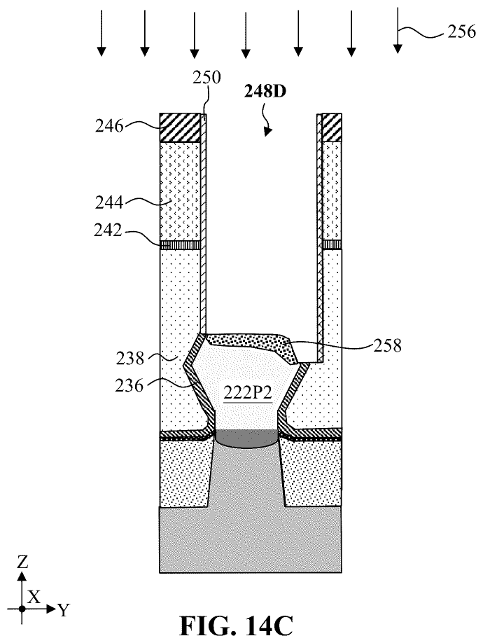

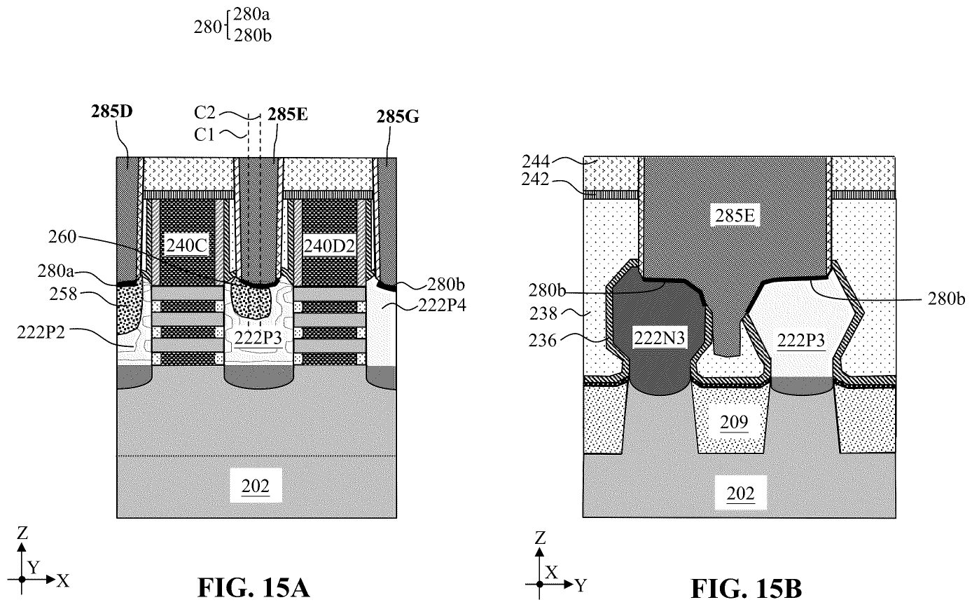

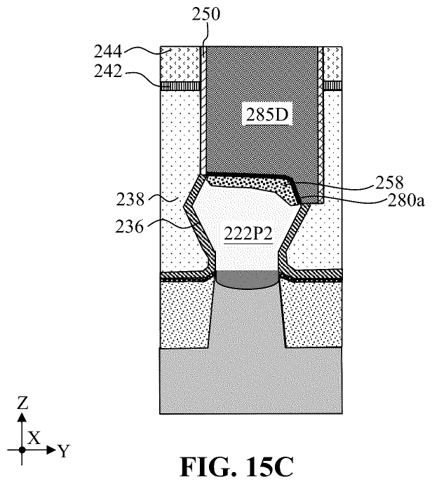

Referring now to FIGS. 4 and 14A-14C, method 100 includes a block 122 where an ion implantation process 256 is performed to the structure 20 while using the patterned protection layer 252 as a doping mask. The patterned protection layer 252 may be selectively removed after the performing of the ion implantation process 256. For the second region 200B, the ion implantation process 256 is performed to dope the P-type source/drain features 222P1-222P2, and a part of the P-type source/drain feature 222P3, while the N-type source/drain features 222N0-222N4 and other P-type source/drain features (e.g., the P-type source/drain feature 222P4 and the other part of the P-type source/drain feature 222P3) are covered. In some embodiments, the ion implantation process 256 includes doping boron, germanium, gallium, other suitable dopants and/or combinations thereof. In an embodiment, dopant of the ion implantation process 256 includes boron, and a concentration of the ¹¹B isotope in the boron is greater than about 99.7%. For example, dopant of the ion implantation process 256 is formed of ¹¹B isotope. The ion implantation process 256 provides relatively heavy and shallow doping on a top portion of the source/drain features (e.g., source/drain feature 222P1, source/drain feature 222P2, and a portion of the source/drain feature 222P3) exposed by the patterned protection layer 252, thereby forming doped regions 258 in the source/drain features 222P1-222P2 and a doped region 260 in the source/drain feature 222P3. Due to the use of the patterned protection layer 252 as the doping mask, the doped region 260 formed in the source/drain feature 222P3 is closer to the gate structure 240C of the pull-up transistor PU-2 than the gate structure 240D2 of the read-port pass gate transistor R-PG. Even though subsequent thermal processes may lead to slightly diffusion of the doped regions 258 and 260, in a final structure, a vertical center line C1 (shown in FIG. 15A) of the doped region 260 is offset form a vertical center line C2 (shown in FIG. 15A) of the source/drain feature 222P3. In addition, since at least a half of a top surface of the source/drain feature 222P3 is covered by the patterned protection layer 252, doping window for forming the doped region 260 is smaller than doping window for forming the doped region 258, and thus, due to, for example, microloading effect, along the Z direction, the doped region 260 spans a depth less than that of the doped region 258, as represented by FIGS. 14A and 15A.

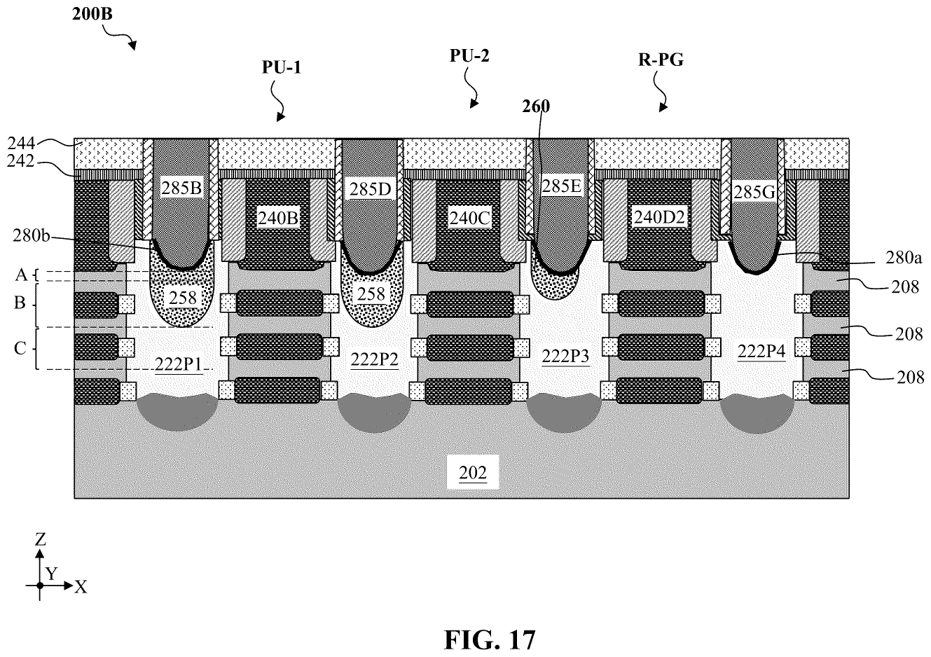

Parameters of the ion implantation process 256 may be configured to form the doped regions 258 and 260 with different dopant concentrations and depths. For example, for the illustrated embodiment in which the transistor include three channel members 208, a region A (shown in FIG. 17) in the source/drain feature 222 is defined as a region between a bottom surface of the outer portion of the gate structure 240 and a horizontal center line of the topmost channel member 208, a region B (shown in FIG. 17) in the source/drain feature 222 is defined as a region between the horizontal center line of the topmost channel member 208 and a horizontal center line of the middle channel member 208, a region C (shown in FIG. 17) in the source/drain feature 222 is defined as a region between the horizontal center line of the middle channel member 208 and a horizontal center line of the bottommost channel member 208.

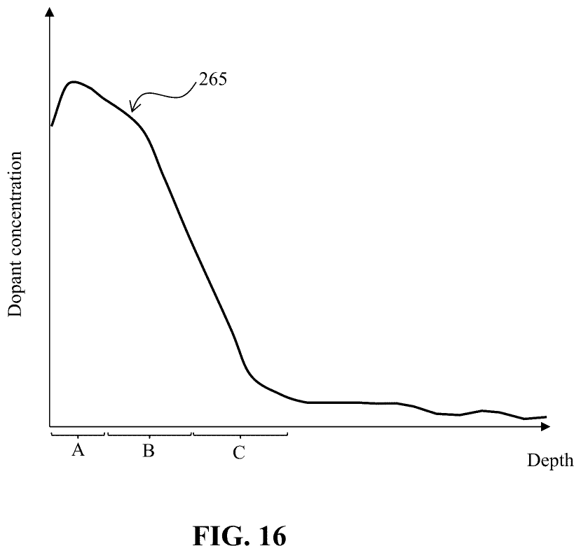

In one embodiment, to mainly drive dopants to form the doped region 258 within the region A, the ion implantation process 256 implants the dopant species using implant energy in a range from about 1.6 KeV to about 3 KeV and the implant dosage is in a range from about 1×10¹⁵ atoms/cm² to about 8×10¹⁵ atoms/cm². In one embodiment, to mainly drive dopants to form the doped region 258 within the regions B and C, the ion implantation process 256 implants the dopant species using implant energy in a range from about 3 KeV to about 4 KeV and the implant dosage is in a range from about 1×10¹⁵ atoms/cm² to about 8×10¹⁵ atoms/cm². In some embodiments, the ion implantation process 256 implements two ion implantations with the parameters described above such that the doped region 258 extends from the region A to the region B/C. FIG. 16 illustrates a curve 265 representing a dopant concentration profile of the doped region 258 in a final structure (e.g., FIGS. 15A and 15C) over a range of depths. As indicated by the curve 265, dopants of the doped region 258 have a gradient profile. It is understood that parameters of the ion implantation process 256 may be adjusted if the transistors have a different number (e.g., 4-10) of channel members.

Referring now to FIGS. 4 and 15A-15C, method 100 includes a block 124 where silicide layers 280 and source/drain contacts 285 are formed in the source/drain contact openings. With reference to FIGS. 15A-15C, after forming the doped regions 258 and the doped region 260, silicide layers 280 and source/drain contacts 285 are formed in the source/drain contact openings 248. To form the silicide layers 280, a metal precursor (e.g., titanium, tantalum, nickel, cobalt, or tungsten) is deposited over the structure 20, including on the exposed surfaces of the source/drain features 222. An anneal process is then performed to bring about silicidation in N-type transistors and germinidation in P-type transistors between the metal precursor and the exposed semiconductor surfaces. In some embodiments, the unreacted metal precursor is selectively removed after the formation of the silicide layers 280. Some of the silicide layers 280 (e.g., 280a) are in direct contact with the doped regions 258 or 260, while other silicide layers 280 (e.g., 280b) are over and in direct contact with the source/drain features 222. For those silicide layers 280a that are in direct contact with the doped regions 258 or 260, for embodiments in which the doped regions 258 and 260 includes dopants formed of ¹¹B, a higher concentration of ¹¹B at the interface between the source/drain features (e.g., source/drain features 222P1-222P3) and the silicide layers 280a thereover may be observed by, for example, atomic prove topography than that related to the silicide layers 280b.

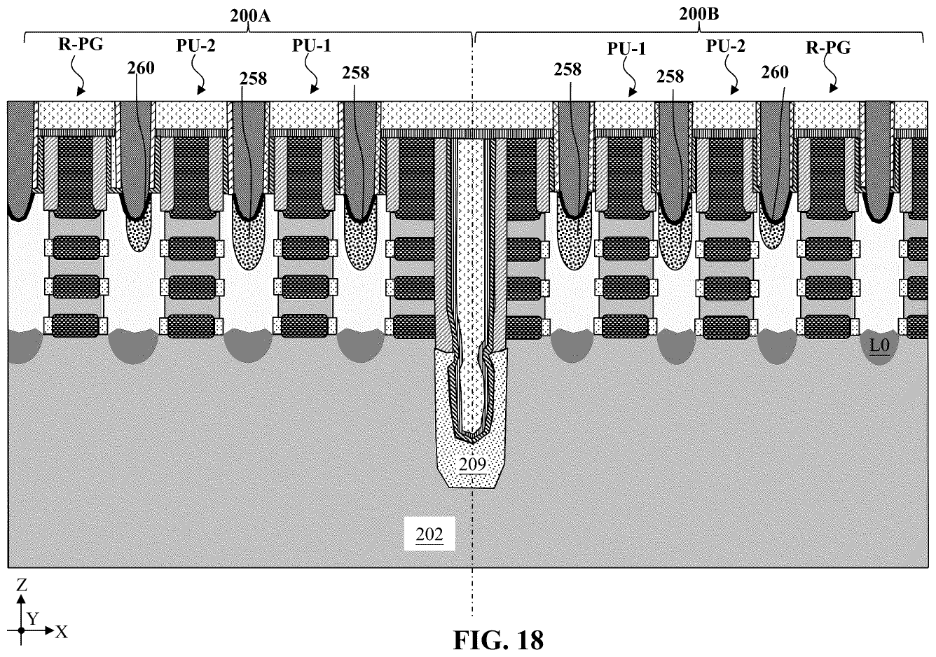

After forming the silicide layers 280, a conductive layer is then deposited over the structure 20, including in the source/drain contact openings 248 and on the silicide layers 280. The conductive layer may include aluminum (Al), copper (Cu), tungsten (W), cobalt (Co), ruthenium (Ru), or molybdenum (Mo) or other suitable materials and may be formed by any suitable deposition processes (e.g., CVD). A planarization process, such as a chemical mechanical polish (CMP) process, may be then performed to remove excess portions of the conductive layer to form the source/drain contacts 285. Although not shown, in some embodiments, the source/drain contacts 285 may further include a conductive barrier layer (e.g., TiN, TaN) extending along sidewall and bottom surfaces of the conductive layer. FIG. 17 depicts a fragmentary cross-sectional view of the p-type transistors (PU-1, PU-2, and R-PG) in the second region 200B of structure 20. FIG. 18 depicts a fragmentary cross-sectional view of the p-type transistors (PU-1, PU-2, and R-PG) in the first and second regions 200A-200B of structure 20, which can also represent a fragmentary cross-sectional view of the structure 20 taken along line A-A shown in FIG. 3.

Referring back to FIG. 4, method 100 includes a block 126 where further processes are performed. After forming the source/drain contacts 285, further processes are performed to finalize the fabrication of the semiconductor structure 20. For example, additional features such as gate vias and interconnect structure(s) may be formed over and/or under the structure 20. In some embodiments, the interconnect structure may include multiple intermetal dielectric (IMD) layers and multiple metal lines or contact vias in each of the IMD layers. In some instances, the IMD layers and the first ILD layer 238 may share similar composition. The metal lines and contact vias in each IMD layer may be formed of metal, such as aluminum, tungsten, ruthenium, or copper. In some embodiments, the metal lines and contact vias may be lined by a barrier layer to prevent or reduce electro-migration.

In the above embodiments described with reference to FIGS. 4-18, to achieve an increased alpha ratio between the pull-up transistors (e.g., PU-1, PU-2) and the read-port pass gate transistor R-PG, the ion implantation process 256 is performed to form the doped regions 258 and 260 from the front side of the substrate 202, and the ion implantation process 296 is performed after the forming of the source/drain contact openings 248 and before the forming of the source/drain contacts 285.

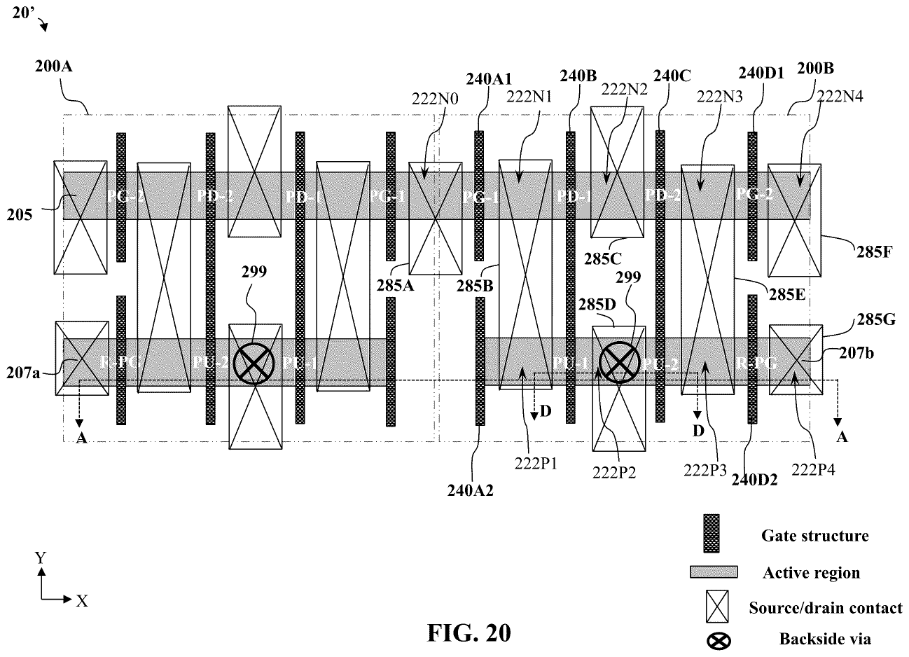

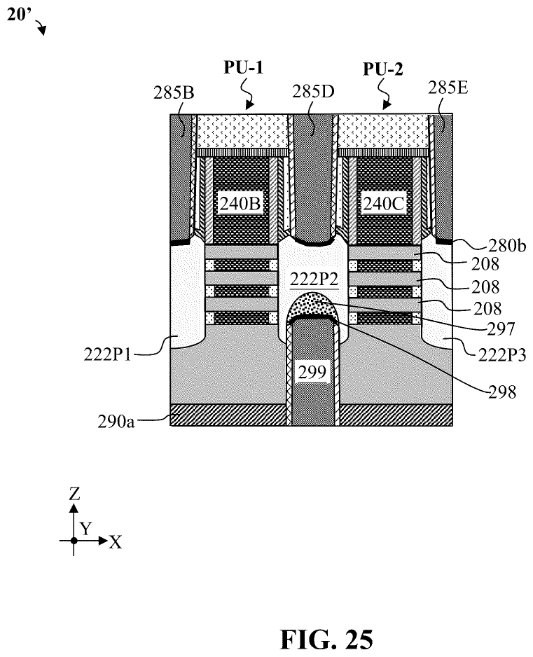

To increase the design flexibility of metal lines over the front side of the substrate 202 and alleviate leakage and overlay issues, metal lines and conductive vias may be formed under the back side of the substrate 202. In another embodiment represented by FIGS. 19-26, an alternative memory device 20′ includes a backside via formed under the source/drain feature 222P2, and another ion implantation process 296 is performed from the back side of the substrate 202 to form a doped region within a lower portion of the source/drain feature 222P2 after the forming of the source/drain contact contacts 285. FIG. 19 depicts a flow chart of a method 100′ for forming the semiconductor structure (e.g., memory device) 20′, according to one or more aspects of the present disclosure, and FIGS. 20-26 illustrate fragmentary layouts and/or cross-sectional views of the semiconductor structure 20′ during various fabrication stages in the method of FIG. 19, according to one or more aspects of the present disclosure. FIG. 20 depicts a fragmentary layout of the semiconductor structure 20′, according to one or more aspects of the present disclosure. The layout of the semiconductor structure 20′ is similar to the layout of the semiconductor structure 20 described above with reference to FIG. 3, and one of the differences includes that, the semiconductor structure 20′ includes a backside via 299 disposed under the source/drain feature 222P2 and in direct contact with a doped region 297 disposed in a lower portion of the source/drain feature 222P2.

Referring to FIG. 19, method 100′ includes blocks 102-118 of method 100. Operations at blocks 102-118 have been described above, and repeated description is omitted for reason of simplicity.

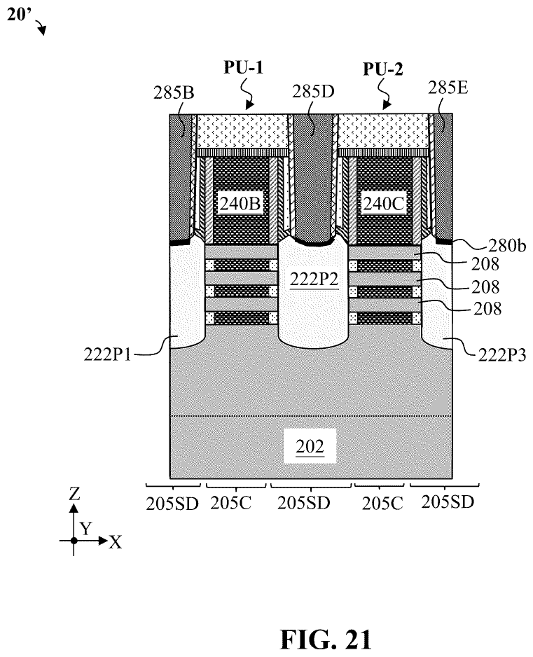

Referring to FIGS. 19 and 21, method 100′ includes a block 150 where silicide layers 280b and source/drain contacts 285 are formed in the source/drain contact openings 248. FIG. 21 depicts a fragmentary cross-sectional view of the semiconductor structure 20′ taken along line D-D shown in FIG. 20. That is, after forming the source/drain contact openings 248 shown in FIGS. 12 and 12A-12C, operations at blocks 120-122 of method 100 is omitted, and the method 100′ proceeds to perform operations at block 150. The formation of the silicide layers 280b and source/drain contacts 285 have been described above, and repeated description is omitted for reason of simplicity.

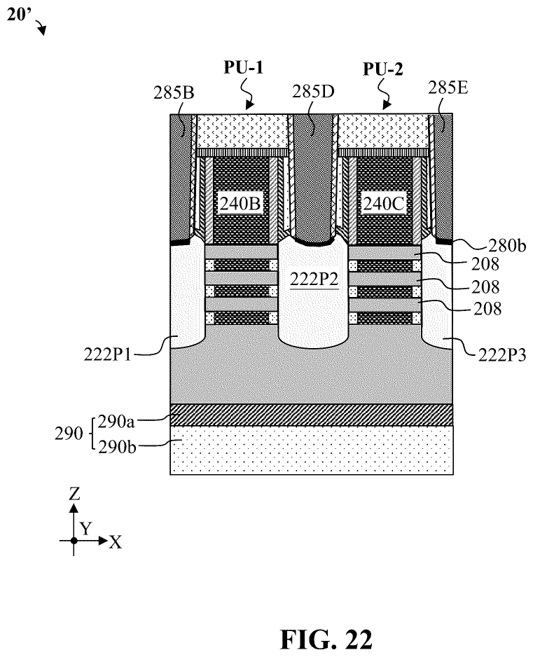

Referring to FIGS. 19 and 22, method 100′ includes a block 152 where a thickness of the substrate 202 is reduced from its back. After forming the silicide layers 280b and source/drain contacts 285, other features such as gate vias and an interconnect structure may be formed over the front side of the substrate 202. A carrier substrate (not shown) is then bonded to the front-side interconnect structure. The carrier substrate may include semiconductor materials (such as silicon), sapphire, glass, polymeric materials, or other suitable materials. Once the carrier substrate is bonded, the structure 20′ is flipped over (not shown). The back side of the structure 20′ is then planarized (e.g., by a planarization process such as a chemical mechanical poshing CMP process) to reduce a thickness of the substrate 202 from its back. In an embodiment, the planarization process may stop after the bottom surface of the STI feature 209 and the top portion 202t of the substrate 202 being exposed. In some embodiments, the planarization process may also remove a portion of the STI feature 209. For ease of description, positional relationships hereafter will be described based on the structure 20′ before the flipping, as depicted in the figures.

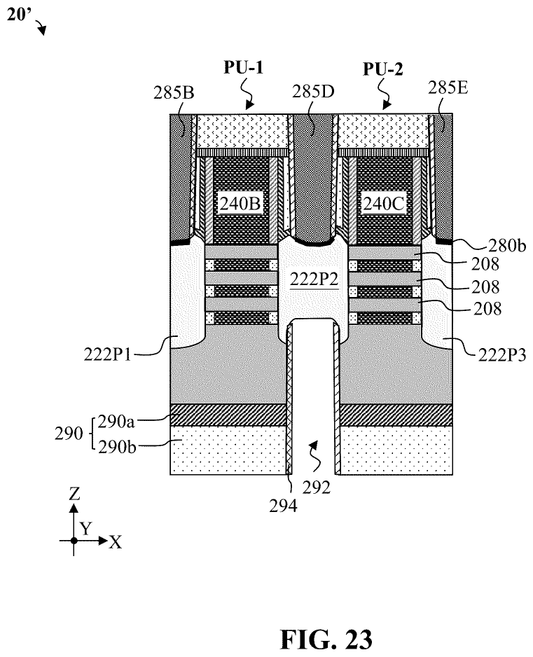

Referring to FIGS. 19 and 22-23, method 100′ includes a block 154 where a trench is formed to expose a bottom surface of the source/drain feature 222P2. With reference to FIG. 22, a patterned dielectric structure 290 is formed under the substrate 202. With reference to FIG. 22, a dielectric structure 290 is formed under the bottom surface of the planarized structure 20′. In the present embodiment, to provide an end point for a subsequent planarization process, the dielectric structure 290 includes a first layer 290a and a second layer 290b having a material composition different than the first layer 290a. In an embodiment, the first layer 290a includes a nitride layer (e.g., silicon nitride), and the second layer 290b includes an oxide layer (e.g., silicon oxide). With reference to FIG. 23, the dielectric structure 290 is patterned to form a trench 292. The trench 292 is disposed directly under at least a part of the source/drain feature 222P2. Then, while using the patterned dielectric structure 290 as an etch mask, an etching process is performed to remove the portion of the substrate 202 disposed directly under the source/drain feature 222P2 to vertically extend the trench 292. As illustrated by FIG. 23, the vertically extended trench 292 extends into source/drain feature 222P2. A dielectric liner 294 may be formed in the vertically extended trench 292. The composition and formation of the dielectric liner 294 may be similar to those of the dielectric liner 250.

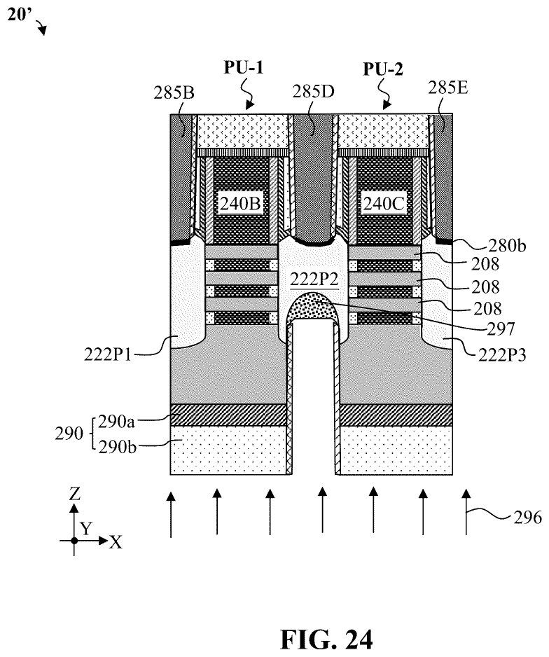

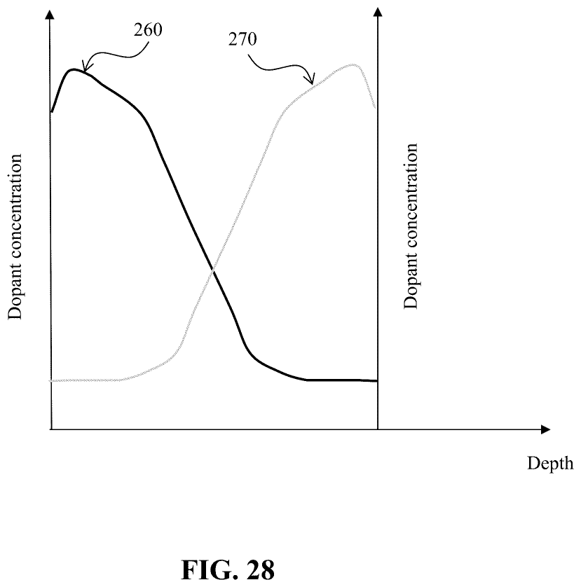

Referring to FIGS. 19 and 24, method 100′ includes a block 156 where an ion implantation process 296 is performed to the structure 20′ while using the patterned dielectric structure 290 as a doping mask. The ion implantation process 296 is similar to the ion implantation process 256, and repeated description is omitted for reason of simplicity. The performing of the ion implantation process 296 forms a doped region 297 in a lower portion of the source/drain feature 222P2. In some embodiments, the doped region 297 can extend into the region C, region B, or even region A (shown in FIG. 17). In some other implementations, the doped region 297 may be below the region C. It is noted that, compared with the ion implantation process 256 which needs a patterned protection layer as a doping mask, performing the ion implantation process 296 does not need to form an extra patterned protection layer as a doping mask. FIG. 28 illustrates a curve 270 representing a dopant concentration profile of the doped region 297 over a range of depths. As indicated by the curve 270, dopants of the doped region 297 have a gradient profile.

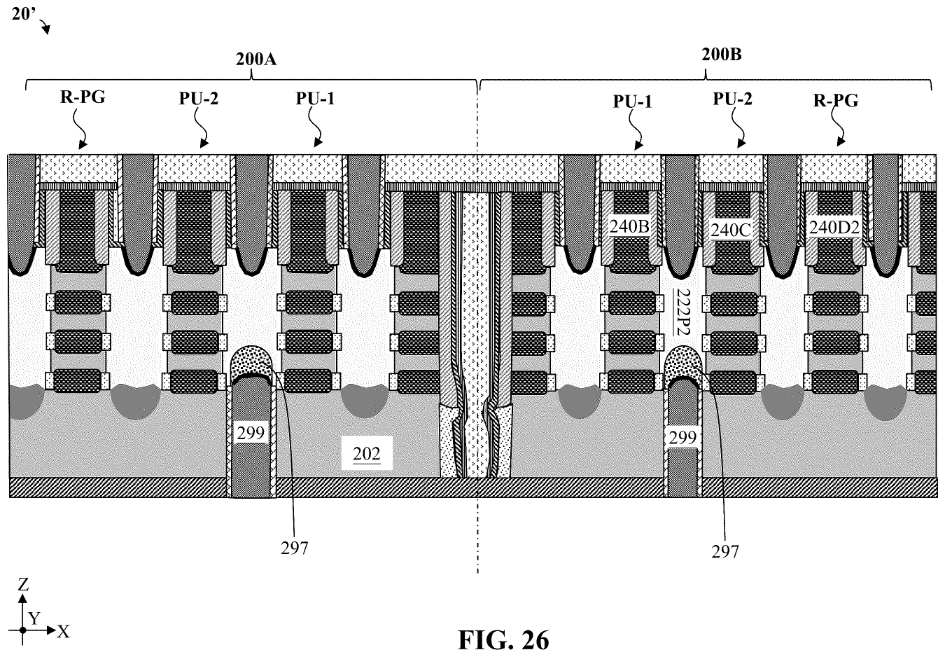

Referring to FIGS. 19 and 25-26, method 100′ includes a block 158 where a silicide layer 298 and a backside via 299 are formed in the vertically extended trench 292. FIG. 26 depicts a fragmentary cross-sectional view of the structure 20′ taken along line A-A shown in FIG. 20. After forming the doped region 297, the silicide layer 298 and backside via 299 are formed. In terms of fabricating processes and compositions, the silicide layer 298 is similar to the silicide layer 280a described above, and the backside via 299 is similar to the source/drain contact 285 described above.

Referring to FIG. 19, method 100′ includes a block 160 where further processes are performed. Such further processes may include forming an interconnect structure under the backside vias 299. In some embodiments, this interconnect structure may include a multiple intermetal dielectric (IMD) layers and multiple metal lines in each of the IMD layers and under the back side of the substrate 202.

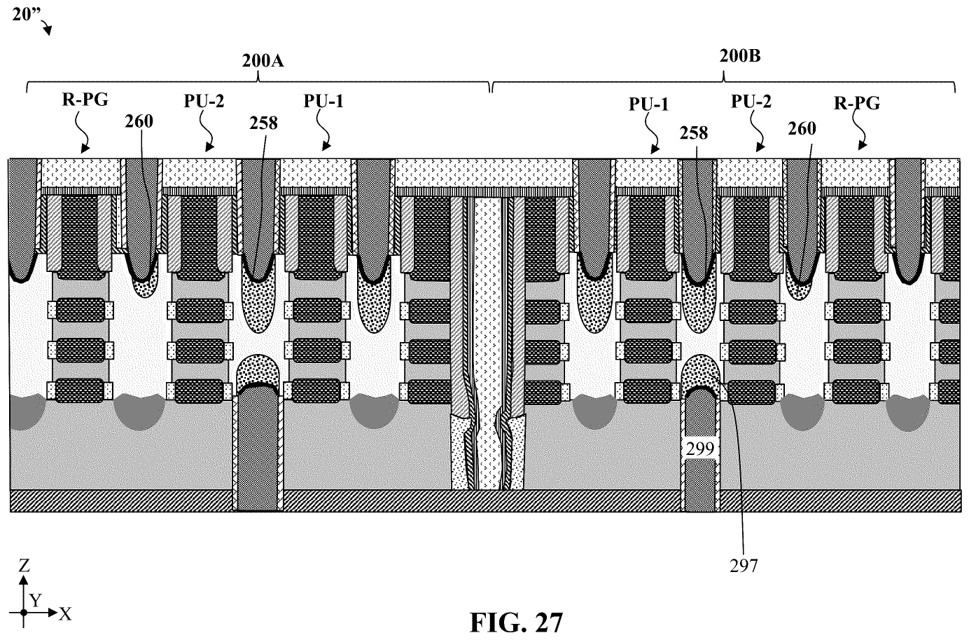

In the above embodiments described with reference to FIGS. 4-26, the structure 20 includes doped regions 258 and 260 formed from the front side of the substrate 202, and the structure 20 includes the doped region 297 formed from the back side of the substrate 202. In another alternative represented by FIG. 27, an alternative structure 20″ includes both the doped regions 258 and 260 formed from the front side of the substrate 202 and the doped region 297 formed from the back side of the substrate 202. FIG. 28 illustrates two curves 265 and 270 of an example of a dopant concentration profile of the doped region 258 and the doped region 297 in the source/drain feature 222P2 over a range of depths. Exemplary steps of forming the structure 20″ may include performing operations at blocks 102-126 of method 100 and then performing operations at blocks 150-160 of method 100′. Those operations have been described in detail above and repeated description is omitted for reason of simplicity.

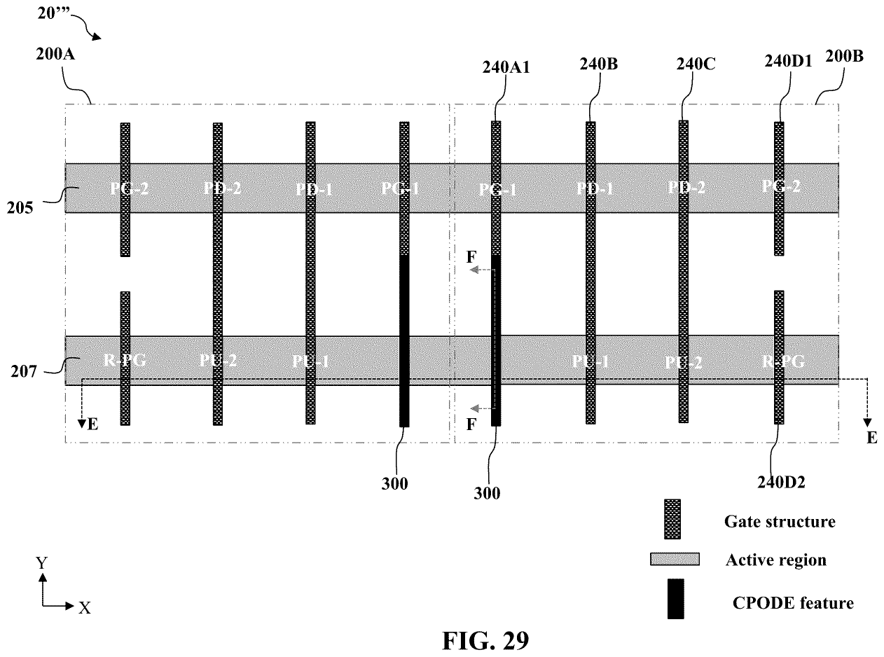

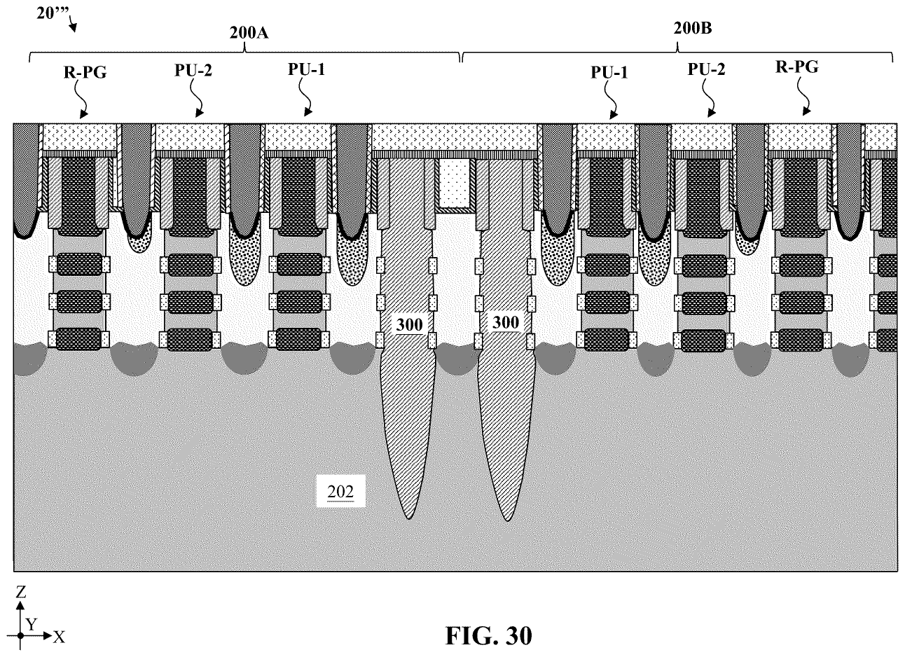

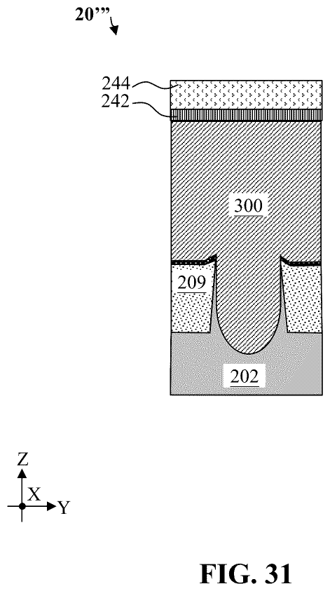

In the above embodiments described with reference to FIGS. 3-28, formation of the structure 20/20′/20″ includes forming the continuous active region 207 and then cut the continuous active region 207 into two segments 207a and 207b using a cut-active-region process. In another alternative embodiment, FIG. 29 illustrates a fragmentary top view of a structure 20′″. FIG. 30 depicts a fragmentary cross-sectional view of the structure 20′″ taken along line E-E shown in FIG. 29, in portion or entirety, according to various aspects of the present disclosure. FIG. 31 depicts a fragmentary cross-sectional view of the structure 20′″ taken along line F-F shown in FIG. 29, in portion or entirety, according to various aspects of the present disclosure. The structure 20′″ is similar to the structure 20, and the differences between the structure 20 and the structure 20′″ include that, the structure 20′″ includes continuous-poly-on-diffusion-edge (CPODE) features 300 configured to cut the continuous active region 207. The CPODE feature 300 is formed in a CPODE process. For purposes of this disclosure, a “diffusion edge” may be equivalently referred to as an active edge, where for example an active edge abuts adjacent active regions. In an example process, an etching process is performed to remove a portion of the dummy gate stack 210 and the channel region of the continuous active region 207 under that portion of the dummy gate stack 210, thereby forming a CPODE trench. The dielectric material filling the CPODE trench for isolation is referred to as a CPODE feature 300. In some embodiments, after the CPODE features 300 are formed, the remaining dummy gate stacks 210 are replaced by metal gate structures 240 in a replacement gate (gate-last) process. and in direct contact with the gate structure 240A1. In FIG. 29, the CPODE feature 300 abuts the gate structure 240A1 and is aligned with the gate structure 240A1. The CPODE feature 300 extends along the Y direction and may further cut another active region 207 of an adjacent SRAM cell (e.g., 200D). That is, two adjacent SRAM cells (e.g., 200B and 200D) may share the CPODE feature 300. The CPODE feature 300 can also be applied to other alternative embodiments described above with reference to FIGS. 19-28.

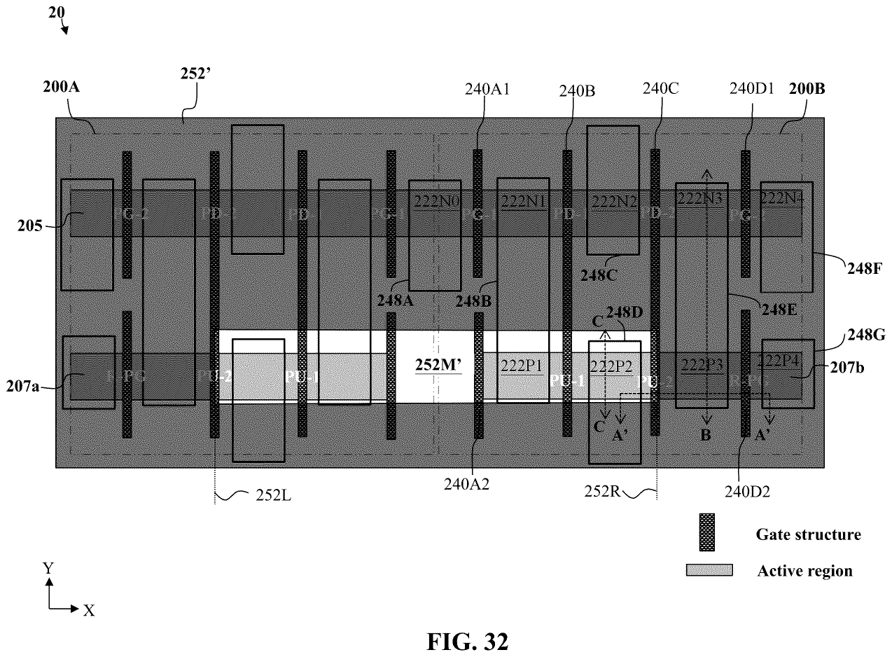

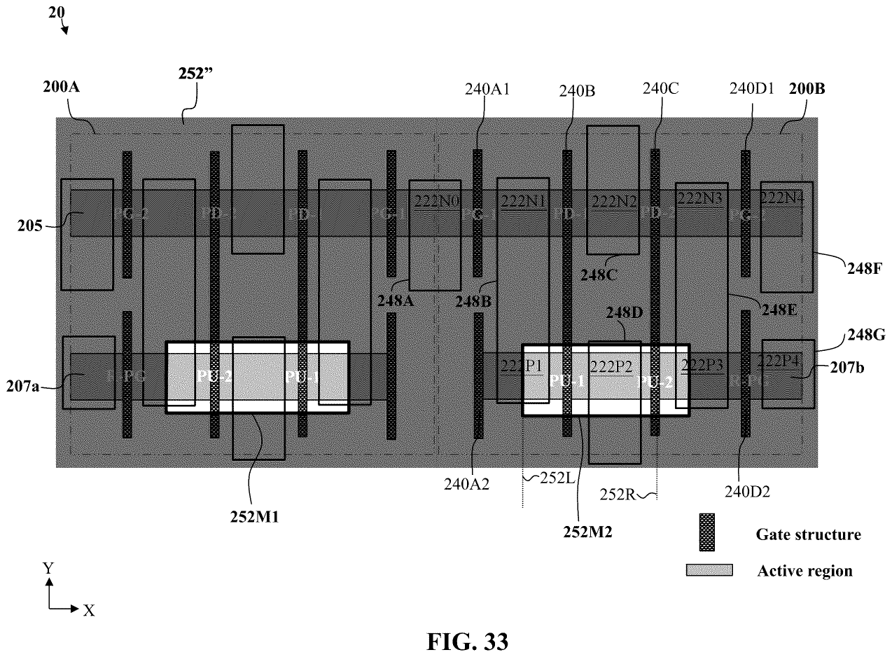

In the above embodiments described with reference to FIGS. 13-28, the patterned protection layer 252 includes one opening 252M′ (shown in FIG. 13) configured to define regions to undergo the subsequent ion implantation process 256 while other regions are protected by the patterned protection layer 252, and the boundary 252R of the opening 252M aligns with a center line of the source/drain feature 222P3. In another alternative embodiment represented by FIG. 32, a different patterned protection layer 252′ with opening 252M′ may be used as the doping mask for the ion implantation process 256. The patterned protection layer 252′ is substantially similar to the patterned protection layer 252, and one difference between them includes that the patterned protection layer 252′ has a different openings 252M′. As represented by FIG. 32, to further increase the alpha ratio between the pull-up transistors (PU-1 and PU-2) and the read-port pass-gate transistor R-PG in the SRAM cell, the opening 252M′ does not expose the source/drain feature 222P3. That is, the boundary 252R may be disposed directly over the gate structure 240C. As a result, the source/drain feature 222P3 will not be doped by the ion implantation process 256 and is free of the doped region 260 described with reference to FIGS. 14A-14C. A final structure of the memory device formed using the patterned protection layer 252′ is thus similar to the memory device 20, and differences between them include that the both two source/drain features (i.e., 222P1 and 222P2) of the pull-up transistor PU-1 include the doped region 258, and both two source/drain features (i.e., 222P3 and 222P4) of the read-port pass-gate transistor do not include the doped region 258/260. Other variations of the patterned protection layer 252 are also possible. For example, the patterned protection layer 252″ shown in FIG. 33 is similar to that patterned protection layer 252 and has an opening 252M1 over the first region 200A and an opening 252M2 over the second region 200B. The opening 252M1 is separated from the opening 252M2. The opening 252M1/252M2 of the patterned protection layer 252 is configured to at least expose the source/drain feature 222P2, and the patterned protection layer 252 is configured to at least cover a half of the source/drain feature 222P3. In other words, when viewed from top, the left boundary 252L may be located between the gate structure 240A2 and the gate structure 240B, and the right boundary 252R may be located between the half of the source/drain feature 222P3 and the gate structure 240B. A final structure of the memory device formed using the patterned protection layer 252″ is thus similar to the memory device 20, and differences between them include that the source/drain features 222P1 and 222P3 may include the doped region 260, the doped region 258, or may be free of the doped region 258/260, depending on the position of the left boundary 252L, and the source/drain feature 222P2 may include the doped region 258. Those patterned protection layers 252′ and 252″ can also be applied to fabricate other alternative structures described above with reference to FIGS. 19-31.

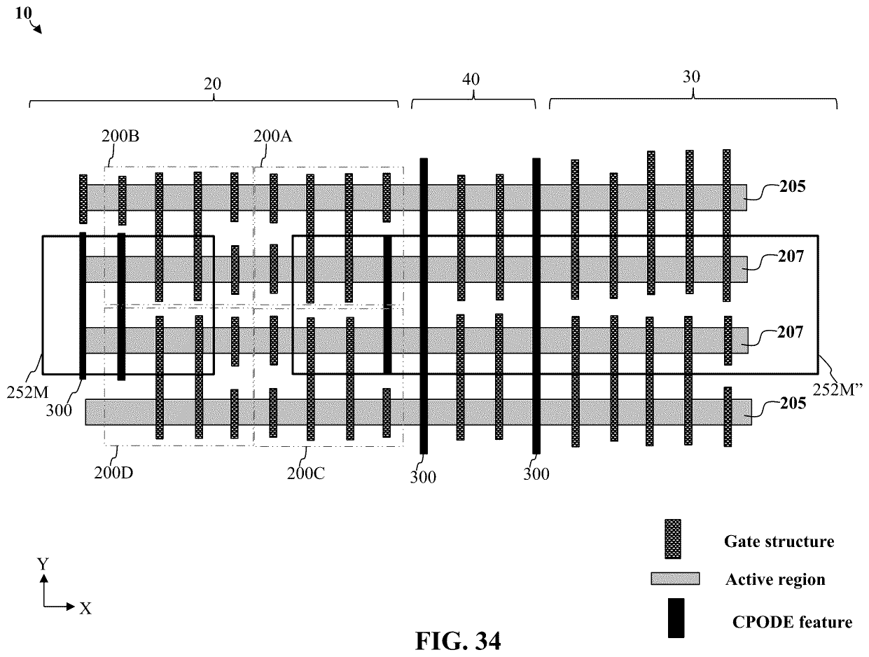

In some embodiments, as represented by FIG. 34, the patterned protection layer 252/252′/252″ also includes an opening exposing P-type transistors in other regions. For example, the IC chip 10 includes at least an array 20 of memory cells (e.g., SRAM cells 200A-200D) and an array 30 of standard logic (STD) cells. A transition region 40 may be disposed between the array 20 and the array 30 to provide isolation between the transistors formed in the array 20 and the transistors formed in the array 30. In an embodiment, the transition region 40 includes two CPODE features 300. The patterned protection layer 252/252′/252″ further includes opening(s) (e.g., 252M″) exposing P-type transistors in the transition region 40 and P-type transistors in the array 30, and source/drain features of those P-type transistors are then doped by the ion implantation process 256 to include the doped regions 258/260 such that those P-type transistors may have enhanced performance. This embodiment can also be combined with other embodiments described above with reference to FIGS. 19-33 to fabricate other alternative structures.

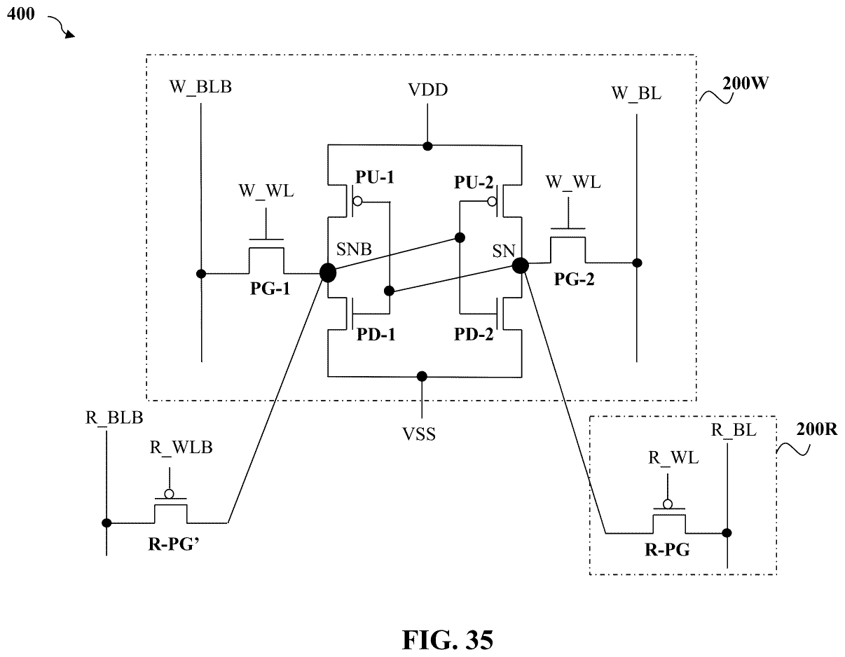

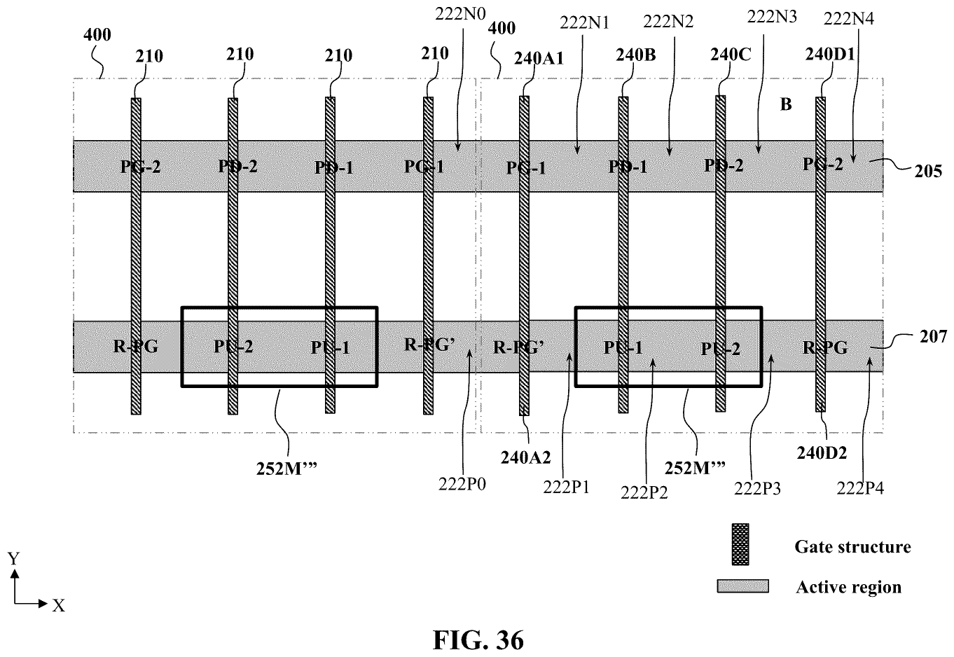

In the above embodiments described with reference to FIGS. 2-34, structures of memory devices including 7T SRAM cells are described. The inventive concepts (e.g., selecting forming the doped regions 258/260/297 to obtain saturation current difference between pull-up transistors and read-port pass-gate transistors R-PG) are also applicable for memory devices including a two-port SRAM cell that has eight transistors (8T). FIG. 35 is a circuit diagram of an 8T SRAM cell 400 that can be implemented in the IC chip of FIG. 1, according to various aspects of the present disclosure. The 8T SRAM cell 400 is similar to the 7T SRAM cell (e.g., SRAM cell 200A/200B/200C/200D), and one difference between the two SRAM cells is that the 8T SRAM cell 400 includes another read-port pass gate transistor R-PG'. FIG. 36 illustrates a simplified fragmentary layout of two 8T SRAM cells 400, according to various aspects of the present disclosure. As represented by FIG. 36, the 8T SRAM cell 400 further includes a p-type source/drain feature 222P0. The read-port pass gate transistor R-PG′ includes the p-type source/drain features 222P0 and 222P1 and the gate structure 240A2. To further increase the saturation current difference (and thus a higher alpha ratio) between pull-up transistors and read-port pass-gate transistors R-PG′, the source/drain feature 222P0 will not be doped by the ion implantation process 256 and/or the ion implantation process 296, the source/drain feature 222P1 may be at most partially doped by the ion implantation process 256 and will not be doped by the ion implantation process 296, in a way similar to that of the source/drain feature 222P3 described above. The patterned protection layer 252 having the opening 252M′″ may be used as dope mask for the ion implantation process 256. Alternative embodiments described above can also be applied to form other 8T SRAM cell 400 and other structures including the 8T SRAM cell 400, and repeated description is omitted for reason of simplicity.

Although not intended to be limiting, one or more embodiments of the present disclosure provide many benefits to a memory device and the formation thereof. It is understood, however, that other embodiments may offer additional advantages, and not all advantages are necessarily disclosed herein, and that no particular advantage is required for all embodiments. For example, the present disclosure provides a memory device including a SRAM cell comprising pull-up transistors and p-type read-port pass gate transistor(s) RPG. One or more ion implantation processes may be selectively applied to source/drain feature(s) of the pull-up transistors, thereby increasing the performance (e.g., a higher saturation current) of the pull-up transistors to obtain a higher alpha ratio. Therefore, read window of the SRAM cell may be advantageously enlarged. In some embodiments, voltage dynamic data retention Vddr of the SRAM cell may improve for about 30 mv to about 80 mv.

The present disclosure provides for many different embodiments. Semiconductor devices and methods of fabrication thereof are disclosed herein. In one exemplary aspect, the present disclosure is directed to a semiconductor device. The semiconductor device includes a memory cell comprising a write port portion and a read port portion electrically coupled to the write port portion. The read port portion includes a p-type transistor (R-PG) having a first source/drain feature having one or more epitaxial layers including p-type dopant, a second source/drain feature substantially the same as the first source/drain feature, and a p-type doped region extended into the one or more epitaxial layers of the first source/drain feature.

In some embodiments, the p-type dopant may include a combination of Boron-11 isotope and Boron-10 isotope. In some embodiments, the p-type doped region may include Boron-11 isotope, germanium (Ge) or gallium (Ga). In some embodiments, the p-type doped region is disposed in a top portion of the first source/drain feature, and the p-type transistor may also include a plurality of nanostructures extending between the first source/drain feature and the second source/drain feature, and a bottom surface of the p-type doped region is lower than a bottom surface of a topmost nanostructure of the plurality of nanostructures. In some embodiments, the semiconductor device may also include a source/drain contact disposed over and electrically coupled to the first source/drain feature, and a center line of the source/drain contact is offset from a center line of the doped region. In some embodiments, the p-type transistor is a first p-type transistor, the p-type doped region is a first p-type doped region, and the write port portion comprises a second p-type transistor having the first source/drain feature, a third source/drain feature, and a second p-type doped region in the third source/drain feature, where the second p-type doped region spans a depth greater than the first p-type doped region. In some embodiments, the write port portion further may include a third p-type transistor having the third source/drain feature, the second p-type doped region in the third source/drain feature, a fourth source/drain feature, and a third p-type doped region in the fourth source/drain feature, wherein the third p-type doped region is substantially the same as the second p-type doped region. In some embodiments, saturation current of the second p-type transistor is greater than saturation current of the first p-type transistor. In some embodiments, the memory cell is a seven-transistor static random access memory (SRAM) cell or an eight-transistor static random access memory (SRAM) cell.

In another exemplary aspect, the present disclosure is directed to a semiconductor device. The semiconductor device includes a first p-type transistor comprising a first gate structure disposed over a first portion of an active region, and a second p-type transistor comprising a second gate structure disposed over a second portion of the active region, where the second p-type transistor comprises a first source/drain feature having a first dopant concentration and a second source/drain feature having a second dopant concentration greater than the first dopant concentration.

In some embodiments, a concentration of Boron-11 isotope in the first source/drain feature is less than a concentration of Boron-11 isotope in the second source/drain feature, and a concentration of Boron-10 isotope in the first source/drain feature is equal to a concentration of Boron-10 isotope in the second source/drain feature. In some embodiments, the first transistor may include the second source/drain feature and a third source/drain feature having a dopant concentration greater than the second dopant concentration. In some embodiments, the second source/drain feature may include a doped epitaxial region having a first dopant and a first doped region extended into the doped epitaxial region and having a second dopant, the third source/drain feature may include another doped epitaxial region having the first dopant and a second doped region extended into the another doped epitaxial region and having the second dopant, the second doped region spans a depth greater than a depth of the first doped region. In some embodiments, the first portion of the active region is disposed directly under the first gate structure and comprises a plurality of nanostructures, a depth of the second doped region is lower than a bottom surface of a topmost nanostructure of the plurality of nanostructures. In some embodiments, the second source/drain feature may include an epitaxial region having a top surface and a bottom surface, a first doped region adjacent to the top surface of the epitaxial region, and a second doped region adjacent to the bottom surface of the epitaxial region and disposed under the first doped region. In some embodiments, the semiconductor device may also include a first silicide layer contacting the first source/drain feature at a first interface, a second silicide layer contacting the second source/drain feature at a second interface, a concentration of Boron-11 isotope of the second interface is greater than a concentration of Boron-11 isotope of the first interface.

In yet another exemplary aspect, the present disclosure is directed to a method. The method includes receiving a transistor comprising a gate structure over a channel region, a first source/drain feature and a second source/drain feature coupled to the channel region, and a dielectric structure over the first source/drain feature and the second source/drain feature, forming a first trench extending through the dielectric structure to expose the first source/drain feature and a second trench extending through the dielectric structure to expose the second source/drain feature, forming a mask layer covering the first trench, wherein an opening of the mask layer exposes a portion of the second trench, after the forming of the mask layer, performing an ion implantation process to form a doped region in the second source/drain feature, and after the performing of the ion implantation process, forming a first source/drain contact in the first trench and a second source/drain contact in the second trench.

In some embodiments, the transistor is a p-type transistor, and the performing of the ion implantation process may include implanting p-type dopants. In some embodiments, the channel region may include a plurality of nanostructures, and the gate structure further wraps around the plurality of nanostructures. In some embodiments, a center line of the doped region is offset from a center line of the second source/drain feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a memory cell comprising:
a write port portion; and
a read port portion electrically coupled to the write port portion and comprising a p-type transistor (R-PG) having:
a first source/drain feature having one or more epitaxial layers including p-type dopant,
a second source/drain feature substantially the same as the first source/drain feature, and
a p-type doped region extended into the one or more epitaxial layers of the first source/drain feature.

2. The semiconductor device of claim 1,
wherein the p-type dopant comprises a combination of Boron-11 isotope and Boron-10 isotope.

3. The semiconductor device of claim 1,
wherein the p-type doped region comprises Boron-11 isotope, germanium (Ge) or gallium (Ga).

4. The semiconductor device of claim 1, wherein the p-type doped region is disposed in a top portion of the first source/drain feature, and the p-type transistor further comprises a plurality of nanostructures extending between the first source/drain feature and the second source/drain feature, wherein a bottom surface of the p-type doped region is lower than a bottom surface of a topmost nanostructure of the plurality of nanostructures.

5. The semiconductor device of claim 1, further comprising:
a source/drain contact disposed over and electrically coupled to the first source/drain feature,
wherein a center line of the source/drain contact is offset from a center line of the doped region.

6. The semiconductor device of claim 1, wherein the p-type transistor is a first p-type transistor, the p-type doped region is a first p-type doped region, and the write port portion comprises a second p-type transistor having:
the first source/drain feature,
a third source/drain feature, and
a second p-type doped region in the third source/drain feature, wherein the second p-type doped region spans a depth greater than the first p-type doped region.

7. The semiconductor device of claim 6, wherein the write port portion further comprises a third p-type transistor having:
the third source/drain feature,
the second p-type doped region in the third source/drain feature,
a fourth source/drain feature, and
a third p-type doped region in the fourth source/drain feature, wherein the third p-type doped region is substantially the same as the second p-type doped region.

8. The semiconductor device of claim 6, wherein saturation current of the second p-type transistor is greater than saturation current of the first p-type transistor.

9. The semiconductor device of claim 1, wherein the memory cell is a seven-transistor static random access memory (SRAM) cell or an eight-transistor static random access memory (SRAM) cell.

10. A semiconductor device, comprising:
a first p-type transistor comprising a first gate structure disposed over a first portion of an active region; and
a second p-type transistor comprising a second gate structure disposed over a second portion of the active region,
wherein the second p-type transistor comprises a first source/drain feature having a first dopant concentration and a second source/drain feature having a second dopant concentration greater than the first dopant concentration.

11. The semiconductor device of claim 10, wherein a concentration of Boron-11 isotope in the first source/drain feature is less than a concentration of Boron-11 isotope in the second source/drain feature, and a concentration of Boron-10 isotope in the first source/drain feature is equal to a concentration of Boron-10 isotope in the second source/drain feature.

12. The semiconductor device of claim 10, wherein the first transistor comprises the second source/drain feature and a third source/drain feature having a dopant concentration greater than the second dopant concentration.

13. The semiconductor device of claim 12,
wherein the second source/drain feature comprises a doped epitaxial region having a first dopant and a first doped region extended into the doped epitaxial region and having a second dopant,
wherein the third source/drain feature comprises another doped epitaxial region having the first dopant and a second doped region extended into the another doped epitaxial region and having the second dopant,
wherein the second doped region spans a depth greater than a depth of the first doped region.

14. The semiconductor device of claim 13,
wherein the first portion of the active region is disposed directly under the first gate structure and comprises a plurality of nanostructures, wherein a depth of the second doped region is lower than a bottom surface of a topmost nanostructure of the plurality of nanostructures.

15. The semiconductor device of claim 10, wherein the second source/drain feature comprises:
an epitaxial region having a top surface and a bottom surface;
a first doped region adjacent to the top surface of the epitaxial region; and
a second doped region adjacent to the bottom surface of the epitaxial region and disposed under the first doped region.

16. The semiconductor device of claim 10, further comprising:
a first silicide layer contacting the first source/drain feature at a first interface; and
a second silicide layer contacting the second source/drain feature at a second interface,
wherein a concentration of Boron-11 isotope of the second interface is greater than a concentration of Boron-11 isotope of the first interface.

17. A method, comprising:
receiving a transistor comprising:
a gate structure over a channel region,
a first source/drain feature and a second source/drain feature coupled to the channel region, and
a dielectric structure over the first source/drain feature and the second source/drain feature;
forming a first trench extending through the dielectric structure to expose the first source/drain feature and a second trench extending through the dielectric structure to expose the second source/drain feature;
forming a mask layer covering the first trench, wherein an opening of the mask layer exposes a portion of the second trench;
after the forming of the mask layer, performing an ion implantation process to form a doped region in the second source/drain feature; and
after the performing of the ion implantation process, forming a first source/drain contact in the first trench and a second source/drain contact in the second trench.

18. The method of claim 17, wherein the transistor is a p-type transistor, and the performing of the ion implantation process comprises implanting p-type dopants.

19. The method of claim 17, wherein the channel region comprises a plurality of nanostructures, and the gate structure further wraps around the plurality of nanostructures.

20. The method of claim 17, wherein a center line of the doped region is offset from a center line of the second source/drain feature.
